(19) United States
(12) Patent Application Publication
(10) Pub. No.: US 2025/0344348 A1
(43) Pub. Date: Nov. 6, 2025

(54) PHASE CHANGE ACTIVE MEMS COOLING SYSTEM

(71) Applicant: Frore Systems Inc., San Jose, CA (US)

(72) Inventors: Suryaprakash Ganti, Los Altos, CA (US); Vikram Mukundan, San Ramon, CA (US); Seshagiri Rao Madhavapeddy, La Jolla, CA (US); Brian James Gally, Los Gatos, CA (US)

(21) Appl. No.: 19/197,718

(22) Filed: May 2, 2025

Related U.S. Application Data
(60) Provisional application No. 63/642,541, filed on May 3, 2024.

(51) Int. Cl. H05K 7/20; B81B 3/00

(52) U.S. Cl. CPC H05K 7/20327; B81B 3/0021; B81B 2201/036

(57) ABSTRACT

A cooling system is described. The cooling system includes a heat-generating structure (e.g. a heat spreader) and a cooling cell coupled with the heat-generating structure. The cooling cell includes a chamber having an active element therein. The active element is configured to undergo vibrational motion when activated. The vibrational motion drives a mixture of a liquid and a gas through the chamber and proximate to the heat-generating structure. At least a portion of the liquid undergoes a liquid-vapor phase change, which transfers heat from the heat-generating structure to the mixture.

### CROSS REFERENCE TO OTHER APPLICATIONS

This application claims priority to U.S. Provisional Patent Application No. 63/642,541 entitled PHASE CHANGE MEMS COOLING SYSTEM filed May 3, 2024 which is incorporated herein by reference for all purposes.

### BACKGROUND OF THE INVENTION

As computing devices grow in speed and computing power, the heat generated by the computing devices also increases. Various mechanisms have been proposed to address the generation of heat. Active devices, such as fans, may be used to drive air through larger computing devices, such as laptop computers or desktop computers. Passive cooling devices, such as heat spreaders, may be used in smaller, mobile computing devices, such as smartphones, virtual reality devices and tablet computers. However, such active and passive devices may be unable to adequately cool not only mobile devices and larger devices, but may also be inadequate for high power computing systems, such as server systems. Server systems utilize multiple high power processors. In addition, servers are typically housed in racks that carry multiple servers systems. Multiple systems that consume large amounts of power and generate large amounts of heat may be placed in proximity. Consequently, additional cooling solutions for computing devices, particularly high power dissipation and low noise solutions, are desired.

### BRIEF DESCRIPTION OF THE DRAWINGS

Various embodiments of the invention are disclosed in the following detailed description and the accompanying drawings.

FIGS. 1A-1G depict an embodiment of an active MEMS cooling system including a centrally anchored cooling element.

FIGS. 2A-2B depict an embodiment of an active MEMS cooling system including a centrally anchored cooling element.

FIGS. 3A-3E depict an embodiment of an active MEMS cooling system formed in a tile.

FIGS. 4A-4B depict an embodiment of an active MEMS cooling system utilizing a phase change and a graph indicating the performance.

FIG. 5 depicts an embodiment of an active MEMS cooling system utilizing a phase change.

FIG. 6 depicts an embodiment of an active MEMS cooling system utilizing a phase change.

FIG. 7 depicts an embodiment of an active MEMS cooling system utilizing a phase change.

FIG. 8 depicts an embodiment of an active MEMS cooling system utilizing a phase change.

FIGS. 9A-9C depict embodiments of an active MEMS cooling system utilizing a phase change and the environment in which the cooling system may be used.

FIG. 10 depicts an embodiment of an active MEMS cooling system utilizing a phase change.

FIG. 11 is a flow chart depicting an embodiment of a method for using an active MEMS cooling system utilizing a phase change.

### DETAILED DESCRIPTION

The invention can be implemented in numerous ways, including as a process; an apparatus; a system; a composition of matter; a computer program product embodied on a computer readable storage medium; and/or a processor, such as a processor configured to execute instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being configured to perform a task may be implemented as a general component that is temporarily configured to perform the task at a given time or a specific component that is manufactured to perform the task. As used herein, the term ‘processor’ refers to one or more devices, circuits, and/or processing cores configured to process data, such as computer program instructions.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

As semiconductor devices become increasingly powerful, the heat generated during operations also grows. For example, processors for mobile devices such as smartphones, tablet computers, notebooks, and virtual reality devices can operate at high clock speeds, but produce a significant amount of heat. Because of the quantity of heat produced, processors may run at full speed only for a relatively short period of time. After this time expires, throttling (e.g. slowing of the processor's clock speed) occurs. Although throttling can reduce heat generation, it also adversely affects processor speed and, therefore, the performance of devices using the processors. As technology moves to 5G and beyond, this issue is expected to be exacerbated.

Larger devices, such as laptop or desktop computers, often include electric fans that have rotating blades. The fan that can be energized in response to an increase in temperature of internal components. The fans drive air through the larger devices to cool internal components. However, such fans are not only too large for some devices, but also may have limited efficacy because of the boundary layer of air existing at the surface of the components, because of a low backpressure when to drive air through devices, because of a limited speed for air flow across the hot surface desired to be cooled, and because of the excessive amount of noise that may be generated. Passive cooling solutions may include components such as a heat spreader and a heat pipe or vapor chamber to transfer heat to a heat exchanger. However, such passive cooling devices may not be sufficient to mitigate heat in some systems. For example, a heat pipe or vapor chamber may provide an insufficient amount of heat transfer to remove excessive heat generated. These issues may be exacerbated for high power systems, such as server and/or machine learning systems, that generate a significant amount of heat. Thus, improved techniques for providing heat dissipation, particularly in high power dissipation systems, are still desired.

A cooling system is described. The cooling system includes a heat-generating structure (e.g. a heat spreader) and a cooling cell coupled with the heat-generating structure. The cooling cell includes a chamber having an active element therein. The active element is configured to undergo vibrational motion when activated. The vibrational motion drives a mixture of a liquid and a gas through the chamber and proximate to the heat-generating structure. In some embodiments, the heat-generating structure may be coupled with other heat generating structure(s). For example, a heat spreader may be thermally coupled to another heat spreader, a vapor chamber, or heat source (e.g., an integrated circuit or battery). At least a portion of the liquid undergoes a liquid-vapor phase change, which transfers heat from the heat-generating structure to the mixture. In some embodiments, the mixture of the liquid and gas driven through the chamber by the vibrational motion includes a vapor phase of the liquid and the gas. Thus, the mixture in the chamber may include the liquid after the portion of the liquid has undergone a phase change. The vibrational motion draws the vapor phase and the gas into and through the chamber.

In some embodiments, a vapor chamber is between the heat-generating structure and the chamber. The vapor chamber includes a high-temperature foam thermally coupled to the heat-generating structure. For example, a metal foam, such as a copper mesh, may be used. The portion of the liquid in the high-temperature foam undergoes the liquid-vapor phase change. Thus, the vibrational motion of the active elements draws the vapor phase and the gas from the vapor chamber into the chamber. In some such embodiments, the vibrational motion reduces a pressure in the vapor chamber below an inactive pressure corresponding to the active element being quiescent. For example, the vibrational motion reduces the pressure by at least 1 kPa, at least 2 kPa, at least 5 kPa, at least 7 kPa, at least 9 kPa, or at least 10 kPa. In some embodiments, the pressure is reduced by not more than 12 kPa (e.g. nominally 10 kPa). The high-temperature foam may be fluidically coupled with a liquid reservoir and physically coupled to the heat-generating structure.

In some embodiments, the cooling cell is coupled with the heat-generating structure such that the vibrational motion draws droplets of the liquid and the gas into the chamber. The mixture of liquid droplets and gas may be driven proximate to the heat-generating structure. The liquid droplets may undergo the liquid-vapor phase change.

In some embodiments, the cooling system includes a vapor collector coupled with the cooling cell. The vapor collector receives the mixture and directing the mixture distal to the cooling cell. In such embodiments, the mixture includes the portion of the liquid in a vapor phase and the gas.

The cooling system may also include a heat recovery subsystem coupled with the cooling cell. The heat recover subsystem receives the portion of the liquid in a vapor phase. Thus, the heat recovery system may use the vapor phase to generate energy. The system may pass the mixture of the vapor phase of the liquid, any other liquid, and the gas back through a chiller and recycle the mixture for further use by the cooling system.

A cooling system including a heat-generating structure (e.g., a heat spreader) and a plurality of cooling cells coupled with the heat-generating structure. Each of the cooling cells includes a chamber having an active element therein. The active element is configured to undergo vibrational motion when activated. The vibrational motion drives a mixture of a liquid and a gas through the chamber and proximate to the heat-generating structure. At least a portion of the liquid undergoes a liquid-vapor phase change. The liquid-vapor phase change transfers heat from the heat-generating structure to the mixture.

In some embodiments, the mixture of the liquid and gas driven through the chamber of each of the cooling cells by the vibrational motion includes a vapor phase of the liquid and the gas. Thus, the vibrational motion draws the vapor phase and the gas into and through the chamber.

In some embodiments, the cooling system also includes a vapor chamber between the heat-generating structure and the cooling cells. The vapor chamber includes a high-temperature foam thermally coupled to the heat-generating structure. The portion of the liquid in the high-temperature foam undergoes the liquid-vapor phase change. The vibrational motion draws the vapor phase and the gas from the vapor chamber into the plurality of cooling cells. The vibrational motion may reduce a pressure in the vapor chamber below an inactive pressure corresponding to the active element being quiescent. For example, the vibrational motion reduces the pressure by at least 1 kPa, at least 2 kPa, at least 5 kPa, at least 7 kPa, at least 9 kPa, or at least 10 kPa. In some embodiments, the pressure is reduced by not more than 12 kPa (e.g. nominally 10 kPa). In some such embodiments, the high-temperature foam is fluidically coupled with a liquid reservoir and physically coupled to the heat-generating structure.

In some embodiments, the cooling cells are coupled with the heat-generating structure such that the vibrational motion draws droplets of the liquid and the gas into the chamber. Thus, the portion of the liquid may undergo the phase change after being driven through the chamber.

The cooling system may also include a vapor collector coupled with the cooling cells. The vapor collector receives the mixture and directs the mixture distal to the cooling cell. The mixture including the portion of the liquid in a vapor phase and the gas.

The cooling system may also include a heat recovery subsystem coupled with the cooling cell. The heat recover subsystem receives the portion of the liquid in a vapor phase.

A method is disclosed. The method includes driving an active element to induce a vibrational motion at a frequency. The active element is in a chamber of a cooling system. The active element is configured to undergo vibrational motion when activated. The vibrational motion drives a mixture of a liquid and a gas through the chamber and proximate to a heat-generating structure. At least a portion of the liquid undergoes a liquid-vapor phase change. The liquid-vapor phase change transfers heat from the heat-generating structure to the mixture.

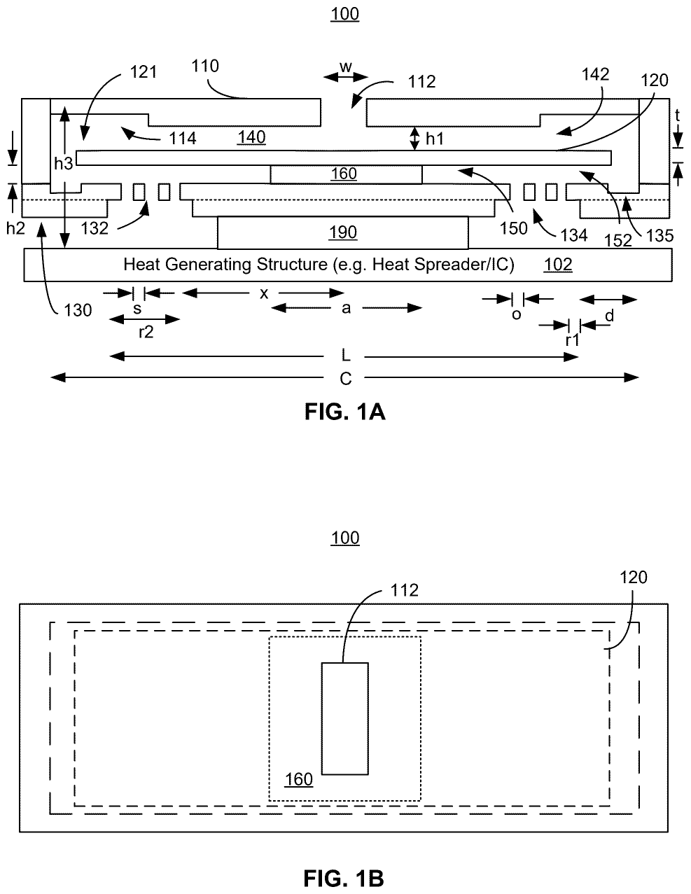

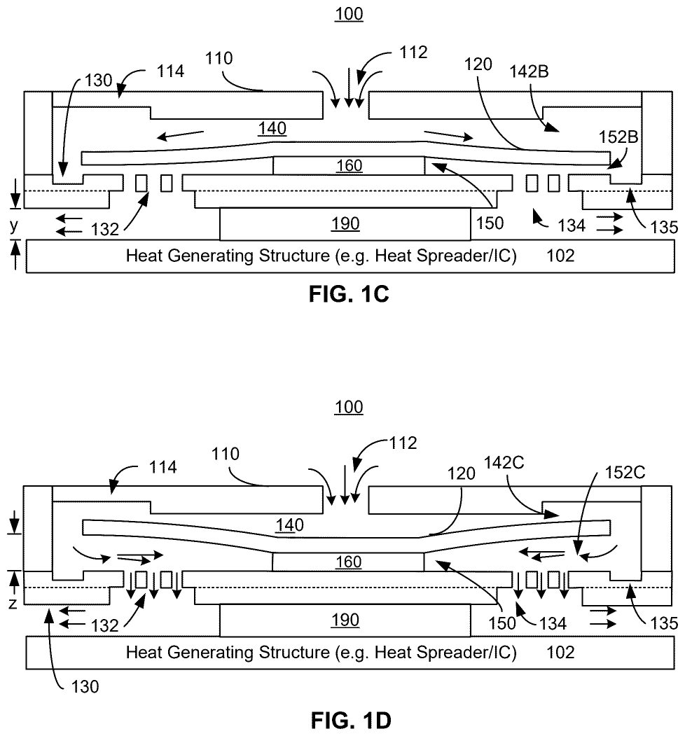

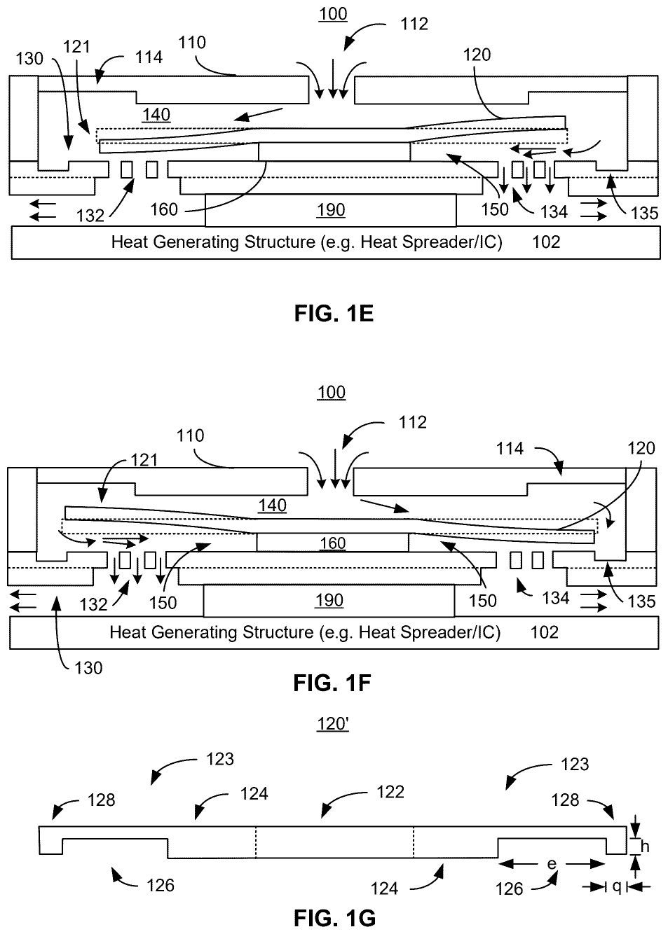

FIGS. 1A-1G are diagrams depicting an exemplary embodiment of active MEMS cooling system 100 usable with heat-generating structure 102 and including a centrally anchored cooling element 120 or 120′. Although termed a cooling system, MEMS system 100 and analogous systems described herein may be considered heat transfer systems and/or fluid transfer systems. Cooling element 120 is shown in FIGS. 1A-1F and cooling element 120′ is shown in FIG. 1G. For clarity, only certain components are shown. FIGS. 1A-1G are not to scale. FIGS. 1A and 1B depict cross-sectional and top views of cooling system 100 in a neutral position. FIGS. 1C-1D depict cooling system 100 during actuation for in-phase vibrational motion. FIGS. 1E-IF depict cooling system 100 during actuation for out-of-phase vibrational motion. Although shown as symmetric, cooling system 100 need not be.

Cooling system 100 includes top plate 110 having vent 112 and cavities 114 therein, cooling element 120, orifice plate 130 having orifices 132 and cavities 134 and 135 therein, support structure (or “anchor”) 160 and chambers 140 and 150 (collectively chamber 140/150) formed therein. Cooling element 120 is supported at its central region by anchor 160. Although termed a cooling element with respect to FIGS. 1A-1G, cooling element 120 and analogous elements described herein may also be considered actuators, vibrating elements, vibrating components, active components, active elements, and/or other terms indicating that the clement is configured to undergo vibrational motion when activated (or energized) and/or to drive fluid through a system. Regions of cooling element 120 closer to and including portions of the cooling element's perimeter (e.g. tip 121) vibrate when actuated. In some embodiments, tip 121 of cooling element 120 includes a portion of the perimeter furthest from anchor 160 and undergoes the largest deflection during actuation of cooling element 120. For clarity, only one tip 121 of cooling element 120 is labeled in FIG. 1A. In some embodiments, vibration of portions of cooling element 120 may cause motion (e.g. rotation) of anchor 160. Also shown is pedestal 190 that connects orifice plate 130 to and offsets orifice plate 130 from heat-generating structure 102. In some embodiments, pedestal 190 also thermally couples orifice plate 130 to heat-generating structure 102. In some embodiments, orifice plate 130 may include an upper plate and a lower, jet channel plate. This is indicated by the dashed line in orifice plate 130. Thus, multiple plates and/or plate(s) having various structures may be used at the bottom plate for cooling system 100.

FIG. 1A depicts cooling system 100 in a neutral position. Thus, cooling element 120 is shown as substantially flat. For in-phase operation, cooling element 120 is driven to vibrate between positions shown in FIGS. IC and 1D. This vibrational motion draws fluid (e.g. air) into vent 112, through chambers 140 and 150 and out orifices 132 at high speed and/or flow rates. The geometry of cooling system 100 may be configured to achieve particular speeds and/or flow rates may for various applications and fluids. For example, the speed at which the fluid (e.g., air) is driven toward heat-generating structure 102 may be at least ten meters per second. In some embodiments, the flow rate through cooling system 100 may be up to approximately 0.08 cubic feet per minute (e.g., at least 0.04 cfm or 0.05 cfm and not more than 0.08 cfm) for air. In some embodiments, the speed may be at least thirty meters per second (e.g. exiting orifices 132 or through the small gap 152B). In some embodiments, the fluid is driven by cooling element 120 toward heat-generating structure 102 at a speed of at least forty-five meters per second. In some embodiments, the fluid is driven toward heat-generating structure 102 by cooling element 120 at speeds of at least sixty meters per second. Other speeds may be possible in some embodiments. Cooling system 100 is also configured so that little or no fluid is drawn back into chamber 140/150 through orifices 132 by the vibrational motion of cooling element 120.

Heat-generating structure 102 is desired to be cooled by cooling system 100. In some embodiments, heat-generating structure 102 generates heat. For example, heat-generating structure may be an integrated circuit. In some embodiments, heat-generating structure 102 is desired to be cooled but does not generate heat itself. Heat-generating structure 102 may conduct heat (e.g. from a nearby object that generates heat). For example, heat-generating structure 102 might be a heat spreader or a vapor chamber. Thus, heat-generating structure 102 may include semiconductor component(s) including individual integrated circuit components such as processors, other integrated circuit(s) and/or chip package(s); sensor(s); optical device(s); one or more batteries; other component(s) of an electronic device such as a computing device; heat spreaders; heat pipes; other electronic component(s) and/or other device(s) desired to be cooled. In some embodiments, heat-generating structure 102 may be a thermally conductive part of a module containing cooling system 100. For example, cooling system 100 may be affixed to heat-generating structure 102, which may be coupled to another heat spreader, a heatsink, vapor chamber, integrated circuit, or other separate structure desired to be cooled.

The devices in which cooling system 100 is desired to be used may also have limited space in which to place a cooling system. For example, cooling system 100 may be used in computing devices. Such computing devices may include but are not limited to smartphones, tablet computers, laptop computers, tablets, two-in-one laptops, hand held gaming systems, digital cameras, virtual reality headsets, augmented reality headsets, mixed reality headsets and other devices that are thin. Cooling system 100 may be a micro-electro-mechanical system (MEMS) cooling system capable of residing within mobile computing devices and/or other devices having limited space in at least one dimension. For example, the total height, h3, of cooling system 100 (from the top of heat-generating structure 102 to the top of top plate 110) may be less than 2 millimeters. In some embodiments, the total height of cooling system 100 is not more than 1.5 millimeters. In some embodiments, this total height is not more than 1.1 millimeters. In some embodiments, the total height does not exceed one millimeter. In some embodiments, the total height does not exceed two hundred and fifty micrometers. Similarly, the distance between the bottom of orifice plate 130 and the top of heat-generating structure 102, y, may be small. In some embodiments, y is at least two hundred micrometers and not more than 1.2 millimeters. For example, y may be at least two hundred and fifty micrometers and not more than three hundred micrometers. In some embodiments, y is at least five hundred micrometers and not more than one millimeter. In some embodiments, y is at least two hundred micrometers and not more than three hundred micrometers. Thus, cooling system 100 is usable in computing devices and/or other devices having limited space in at least one dimension. However, nothing prevents the use of cooling system 100 in devices having fewer limitations on space and/or for purposes other than cooling. Although one cooling system 100 is shown (e.g. one cooling cell), multiple cooling systems 100 might be used in connection with heat-generating structure 102. For example, a one or two-dimensional array of cooling cells might be utilized.

Cooling system 100 is in communication with a fluid used to cool heat-generating structure 102. The fluid may be a gas and/or a liquid. For example, the fluid may be air, air combined with liquid vapor, or a liquid. In some embodiments, the fluid includes fluid from outside of the device in which cooling system 100 resides (e.g. provided through external vents in the device). In some embodiments, the fluid circulates within the device in which cooling system 100 resides (e.g. in an enclosed device).

Cooling element 120 can be considered to divide the interior of active MEMS cooling system 100 into top chamber 140 and bottom chamber 150. Top chamber 140 is formed by cooling clement 120, the sides, and top plate 110. Bottom chamber 150 is formed by orifice plate 130, the sides, cooling element 120 and anchor 160. Top chamber 140 and bottom chamber 150 are connected at the periphery of cooling element 120 and together form chamber 140/150 (e.g. an interior chamber of cooling system 100).

The size and configuration of top chamber 140 may be a function of the cell (cooling system 100) dimensions, cooling element 120 motion, and the frequency of operation. Top chamber 140 has a height, h1. The height of top chamber 140 may be selected to provide sufficient pressure to drive the fluid to bottom chamber 150 and through orifices 132 at the desired flow rate and/or speed. Top chamber 140 is also sufficiently tall that cooling element 120 does not contact top plate 110 when actuated. The magnitude of the deflection of cooling clement 120 may also be tailored by, for example, changing the driving voltage of the signal used to drive vibration of cooling element 120. In some embodiments, the height of top chamber 140 is at least fifty micrometers and not more than five hundred micrometers. In some embodiments, top chamber 140 has a height of at least two hundred and not more than three hundred micrometers.

Bottom chamber 150 has a height, h2. In some embodiments, the height of bottom chamber 150 is sufficient to accommodate the motion of cooling element 120. For example, the height of bottom chamber 150 may be sufficiently large to accommodate the maximum amplitude of vibration of cooling element 120. Thus, no portion of cooling element 120 contacts orifice plate 130 during normal operation in some embodiments. Bottom chamber 150 is generally smaller than top chamber 140 and may aid in reducing the backflow of fluid into orifices 132. In some embodiments, the height of bottom chamber 150 is the maximum deflection of cooling element 120 plus at least five micrometers and not more than ten micrometers. In some embodiments, the deflection of cooling element 120 (e.g. the deflection of tip 121), z, has an amplitude of at least ten micrometers and not more than one hundred micrometers. In some such embodiments, the amplitude of deflection of cooling element 120 is at least ten micrometers and not more than sixty micrometers. However, the amplitude of deflection of cooling element 120 depends on factors such as the desired flow rate through cooling system 100 and the configuration of cooling system 100. Thus, the height of bottom chamber 150 generally depends on the flow rate through and other components of cooling system 100.

Top plate 110 includes vent 112 through which fluid may be drawn into cooling system 100. Top vent 112 may have a size chosen based on the desired acoustic pressure in chamber 140. For example, in some embodiments, the width, w, of vent 112 is at least five hundred micrometers and not more than one thousand micrometers. In some embodiments, the width of vent 112 is at least two hundred fifty micrometers and not more than two thousand micrometers. In the embodiment shown, vent 112 is a centrally located aperture in top plate 110. In other embodiments, vent 112 may be located elsewhere. For example, vent 112 may be closer to one of the edges of top plate 110. Vent 112 may have a circular, rectangular or other shaped footprint. Although a single vent 112 is shown, multiple vents might be used. For example, vents may be offset toward the edges of top chamber 140 or be located on the side(s) of top chamber 140. Top plate 110 also includes cavities 114 therein. Cavities 114 may facilitate vibration of cooling element 120 by moderating the pressure variation near tip of cooling element 120. In other embodiments, cavities 114 may be omitted and top plate 110 may be substantially flat. In some embodiments, other and/or additional trenches and/or other structures may be provided in top plate 110 to modify the configuration of top chamber 140 and/or the region above top plate 110.

Anchor (support structure) 160 supports cooling element 120 at the central portion of cooling element 120. Thus, at least part of the perimeter of cooling element 120 is unpinned and free to vibrate. In some embodiments, anchor 160 extends along a central axis of cooling element 120 (e.g. perpendicular to the page in FIGS. 1A and 1C-1F). In such embodiments, portions of cooling element 120 that vibrate (e.g. including tip 121) move in a cantilevered fashion. Thus, portions of cooling element 120 may move in a manner analogous to the wings of a butterfly (i.e. in phase) and/or analogous to a see-saw (i.e. out of phase). Thus, the portions of cooling element 120 that vibrate in a cantilevered fashion do so in phase in some embodiments and out of phase in other embodiments. In some embodiments, anchor 160 does not extend along an axis of cooling element 120. In such embodiments, all portions of the perimeter of cooling element 120 are free to vibrate (e.g. analogous to a jellyfish). In the embodiment shown, anchor 160 supports cooling element 120 from the bottom of cooling element 120. In other embodiments, anchor 160 may support cooling element 120 in another manner. For example, anchor 160 may support cooling element 120 from the top (e.g. cooling clement 120 hangs from anchor 160). In some embodiments, the width, a, of anchor 160 is at least 0.5 millimeters and not more than four millimeters. In some embodiments, the width of anchor 160 is at least two millimeters and not more than 2.5 millimeters. Anchor 160 may occupy at least ten percent and not more than fifty percent of cooling element 120.

Cooling element 120 has a first side distal from heat-generating structure 102 and a second side proximate to heat-generating structure 102. In the embodiment shown in FIGS. 1A and 1C-1F, the first side of cooling element 120 is the top of cooling element 120 (closer to top plate 110) and the second side is the bottom of cooling element 120 (closer to orifice plate 130). Cooling element 120 is actuated to undergo vibrational motion as shown in FIGS. 1A and 1C-1F. The vibrational motion of cooling clement 120 drives fluid from the first side of cooling element 120 distal from heat-generating structure 102 (e.g. from top chamber 140) to a second side of cooling element 120 proximate to heat-generating structure 102 (e.g. to bottom chamber 150). The vibrational motion of cooling element 120 also draws fluid through vent 112 and into top chamber 140; forces fluid from top chamber 140 to bottom chamber 150; and drives fluid from bottom chamber 150 through orifices 132 of orifice plate 130. Thus, cooling element 120 may be viewed as an actuator. Although described in the context of a single, continuous cooling element, in some embodiments, cooling element 120 may be formed by two (or more) cooling elements. Each of the cooling elements is depicted as one portion pinned (e.g. supported by support structure 160) and an opposite portion unpinned. Thus, a single, centrally supported cooling element 120 may be formed by a combination of multiple cooling elements supported at an edge.

Cooling element 120 has a length, L, that depends upon the frequency at which cooling element 120 is desired to vibrate. In some embodiments, the length of cooling element 120 is at least four millimeters and not more than ten millimeters. In some such embodiments, cooling element 120 has a length of at least six millimeters and not more than eight millimeters. The depth of cooling element 120 (e.g. perpendicular to the plane shown in FIGS. 1A and 1C-1F) may vary from one fourth of L through twice L. For example, cooling element 120 may have the same depth as length. The thickness, t, of cooling element 120 may vary based upon the configuration of cooling element 120 and/or the frequency at which cooling element 120 is desired to be actuated. In some embodiments, the cooling element thickness is at least two hundred micrometers and not more than three hundred and fifty micrometers for cooling element 120 having a length of eight millimeters and driven at a frequency of at least twenty kilohertz and not more than twenty-five kilohertz. The length, C, of chamber 140/150 is close to the length, L, of cooling element 120. For example, in some embodiments, the distance, d, between the edge of cooling element 120 and the wall of chamber 140/150 is at least one hundred micrometers and not more than five hundred micrometers. In some embodiments, d is at least two hundred micrometers and not more than three hundred micrometers.

Cooling element 120 may be driven at a frequency that is at or near both the resonant frequency for an acoustic resonance of a pressure wave of the fluid in top chamber 140 and the resonant frequency for a structural resonance of cooling element 120. The portion of cooling element 120 undergoing vibrational motion is driven at or near resonance (the “structural resonance”) of cooling element 120. This portion of cooling element 120 undergoing vibration may be a cantilevered section. The frequency of vibration for structural resonance is termed the structural resonant frequency. Use of the structural resonant frequency in driving cooling clement 120 reduces the power consumption of cooling system 100. Cooling element 120 and top chamber 140 may also be configured such that this structural resonant frequency corresponds to a resonance in a pressure wave in the fluid being driven through top chamber 140 (the acoustic resonance of top chamber 140). The frequency of such a pressure wave is termed the acoustic resonant frequency. At acoustic resonance, a node in pressure occurs near vent 112 and an antinode in pressure occurs near the periphery of cooling system 100 (e.g. near tip 121 of cooling clement 120 and near the connection between top chamber 140 and bottom chamber 150). The distance between these two regions is C/2. Thus, C/2=nλ/4, where λ is the acoustic wavelength for the fluid and n is odd (e.g. n=1, 3, 5, etc.). For the lowest order mode, C=λ/2. Because the length of chamber 140 (e.g. C) is close to the length of cooling element 120, in some embodiments, it is also approximately true that L/2=nλ/4, where A is the acoustic wavelength for the fluid and n is odd. Thus, the frequency at which cooling element 120 is driven, v, is at or near the structural resonant frequency for cooling element 120. The frequency v is also at or near the acoustic resonant frequency for at least top chamber 140. The acoustic resonant frequency of top chamber 140 generally varies less dramatically with parameters such as temperature and size than the structural resonant frequency of cooling clement 120. Consequently, in some embodiments, cooling element 120 may be driven at (or closer to) a structural resonant frequency rather than to the acoustic resonant frequency.

Orifice plate 130 has orifices 132 and cavities 134 and 135 therein. Although a particular number and distribution of orifices 132 and cavities 134 and 135 are shown, another number and/or another distribution may be used. Cavities 134 and/or 135 may be configured differently or may be omitted. In some embodiments, other cavities may be within flow chamber 140/150 or the jet channel between orifice plate 130 and heat-generating structure 102. Cavity 135 may assist in capturing dust entering flow chamber 140/150 and/or may enhance fluid flow. A single orifice plate 130 is used for a single cooling system 100. In other embodiments, multiple cooling systems 100 may share an orifice plate. For example, multiple cells 100 may be provided together in a desired configuration. In such embodiments, the cells 100 may be the same size and configuration or different size(s) and/or configuration(s). Orifices 132 are shown as having an axis oriented normal to a surface of heat-generating structure 102. In other embodiments, the axis of one or more orifices 132 may be at another angle. For example, the angle of the axis may be from substantially zero degrees through a nonzero acute angle from normal to the surface. Orifices 132 also have sidewalls that are substantially parallel to the normal to the surface of orifice plate 130. In some embodiments, orifices may have sidewalls at a nonzero angle to the normal to the surface of orifice plate 130. For example, orifices 132 may be cone-shaped. Further, although orifice place 130 is shown as having a particular configuration, other configurations are possible.

The size, number, distribution, and locations of orifices 132 are chosen to control the flow rate of fluid driven to the surface of heat-generating structure 102. The locations and configurations of orifices 132 may be configured to increase the fluid flow from bottom chamber 150 through orifices 132 to the jet channel (the region between the bottom of orifice plate 130 and the top of heat-generating structure 102). The locations and configurations of orifices 132 may also be selected to reduce the suction flow (e.g. back flow) from the jet channel through orifices 132. In some embodiments, the ratio of the flow rate from top chamber 140 into bottom chamber 150 to the flow rate from the jet channel through orifices 132 (the “net flow ratio”) is greater than 2:1. In some embodiments, the net flow ratio is at least 85:15. In some embodiments, the net flow ratio is at least 90:10. In order to provide the desired pressure, flow rate, suction, and net flow ratio, orifices 132 may be desired to be at least a distance, r1, from tip 121 and not more than a distance, r2, from tip 121 of cooling element 120. In some embodiments, r1 is at least one hundred micrometers (e.g. r1≥100 μm) and r2 is not more than one millimeter (e.g. r2≤1000 μm). In some embodiments, orifices 132 are at least two hundred micrometers from tip 121 of cooling element 120 (e.g. r1≥200 μm). In some such embodiments, orifices 132 are at least three hundred micrometers from tip 121 of cooling element 120 (e.g. r1≥300 μm). In some embodiments, orifices 132 have a width, o, of at least one hundred micrometers and not more than five hundred micrometers. In some embodiments, orifices 132 have a width of at least two hundred micrometers and not more than three hundred micrometers. In some embodiments, the orifice separation, s, is at least one hundred micrometers and not more than one millimeter. In some such embodiments, the orifice separation is at least four hundred micrometers and not more than six hundred micrometers. In some embodiments, orifices 132 are also desired to occupy a particular fraction of the area of orifice plate 130. For example, orifices 132 may cover at least five percent and not more than fifteen percent of the footprint of orifice plate 130 in order to achieve a desired flow rate of fluid through orifices 132. In some embodiments, orifices 132 cover at least eight percent and not more than twelve percent of the footprint of orifice plate 130.

In some embodiments, cooling element 120 is actuated using a piezoelectric material. Cooling element 120 may be driven by a piezoelectric material that is mounted on or integrated into cooling element 120. In some embodiments, cooling element 120 is driven in another manner including but not limited to providing a piezoelectric material on another structure in cooling system 100. Cooling element 120 and analogous cooling elements are referred to hereinafter as piezoelectric cooling elements though it is possible that a mechanism other than a piezoelectric material might be used to drive the cooling element. In some embodiments, cooling element 120 includes a piezoelectric layer on substrate. The substrate may include or consist of stainless steel, a Ni alloy, Hastelloy, Al (e.g. an Al alloy), and/or Ti (e.g. a Ti alloy such as Ti6Al-4V). In some embodiments, a piezoelectric layer includes multiple sublayers formed as thin films on the substrate. In other embodiments, the piezoelectric layer may be a bulk layer affixed to the substrate. Such a piezoelectric cooling element 120 also includes electrodes used to activate the piezoelectric material. The substrate functions as an electrode in some embodiments. In other embodiments, a bottom electrode may be provided between the substrate and the piezoelectric layer. Other layers including but not limited to seed, capping, passivation, or other layers might be included in the piezoelectric cooling element. Thus, cooling clement 120 may be actuated using a piezoelectric material.

In some embodiments, cooling system 100 includes chimneys (not shown) and/or other ducting. Such ducting provides a path for heated fluid to flow away from heat-generating structure 102. In some embodiments, ducting returns fluid to the side of top plate 110 distal from heat-generating structure 102. In some embodiments, ducting may instead direct fluid away from heat-generating structure 102. Thus, the fluid is allowed to carry away heat from heat-generating structure 102.

Operation of cooling system 100 is described in the context of FIGS. 1A and 1C-1F. Although described in the context of particular pressures, gap sizes, and timing of flow, operation of cooling system 100 is not dependent upon the explanation herein. FIGS. IC-1D depict in-phase operation of cooling system 100. Referring to FIG. 1C, cooling element 120 has been actuated so that its tip 121 moves away from top plate 110. FIG. 1C can thus be considered to depict the end of a down stroke of cooling element 120. Because of the vibrational motion of cooling clement 120, gap 152 for bottom chamber 150 has decreased in size and is shown as gap 152B. Conversely, gap 142 for top chamber 140 has increased in size and is shown as gap 142B. Because top chamber 140 increases in size, a lower pressure is present in top chamber 140. Because bottom chamber 150 has decreased in size, a higher pressure is present at gap 152B.

Cooling element 120 is also actuated so that tip 121 moves away from heat-generating structure 102 and toward top plate 110. FIG. 1D can thus be considered to depict the end of an up stroke of cooling element 120. Because of the motion of cooling element 120, gap 142 has decreased in size and is shown as gap 142C. Gap 152 has increased in size and is shown as gap 152C. Thus, a higher pressure is present near gap 142C, while a lower pressure is present near gap 152C. The net motion of fluid through chamber 140/150 is indicated in FIGS. IC and 1D by unlabeled arrows. However, the unlabeled arrows in FIGS. 1C and 1D are not intended to indicate the motion of fluid at a particular time. Thus, cooling system 100 is able to drive fluid from top chamber 140 to bottom chamber 150 without an undue amount of backflow of heated fluid from the jet channel entering bottom chamber 150. Moreover, cooling system 100 may operate such that fluid is drawn in through vent 112 and driven out through orifices 132 without cooling element 120 contacting top plate 110 or orifice plate 130. Thus, pressures are developed within chambers 140 and 150 that effectively open and close vent 112 (e.g., by pressures near gap 142/142B/142C) and orifices 132 (e.g. by pressures near gap 152/152B/152C) such that fluid is driven through cooling system 100 as described herein.

The motion between the positions shown in FIGS. 1C and 1D is repeated. Thus, cooling element 120 undergoes vibrational motion indicated in FIGS. 1A-1D, drawing fluid through vent 112 from the distal side of top plate 110 into top chamber 140; transferring fluid from top chamber 140 to bottom chamber 150; and pushing the fluid through orifices 132 and toward heat-generating structure 102. As discussed above, cooling element 120 is driven to vibrate at or near the structural resonant frequency of cooling element 120. Further, the structural resonant frequency of cooling element 120 is configured to align with the acoustic resonance of the chamber 140/150. The structural and acoustic resonant frequencies are generally chosen to be in the ultrasonic range. For example, the vibrational motion of cooling element 120 may be at frequencies from 15 kHz through 30 kHz. In some embodiments, cooling element 120 vibrates at a frequency/frequencies of at least 20 kHz and not more than 30 kHz. In some embodiments, cooling element vibrates at a frequency of at least 23 kHz and not more than 26 kHz. The structural resonant frequency of cooling element 120 is within ten percent of the acoustic resonant frequency of cooling system 100. In some embodiments, the structural resonant frequency of cooling element 120 is within five percent of the acoustic resonant frequency of cooling system 100. In some embodiments, the structural resonant frequency of cooling element 120 is within three percent of the acoustic resonant frequency of cooling system 100. Consequently, efficiency and flow rate may be enhanced. However, other frequencies may be used.

Fluid driven toward heat-generating structure 102 may move substantially normal (perpendicular) to the top surface of heat-generating structure 102. In some embodiments, the fluid motion may have a nonzero acute angle with respect to the normal to the top surface of heat-generating structure 102. In either case, the fluid may thin and/or form apertures in the boundary layer of fluid at heat-generating structure 102. As a result, transfer of heat from heat-generating structure 102 may be improved. The fluid travels along the surface of heat-generating structure 102. Thus, heat from heat-generating structure 102 may be extracted by the fluid. The fluid may exit the region between orifice plate 130 and heat-generating structure 102 at the edges of cooling system 100. Chimneys or other ducting (not shown) at the edges of cooling system 100 allow fluid to be carried away from heat-generating structure 102. In other embodiments, heated fluid may be transferred further from heat-generating structure 102 in another manner. The fluid may exchange the heat transferred from heat-generating structure 102 to another structure or to the ambient environment. Thus, fluid at the distal side of top plate 110 may remain relatively cool, allowing for the additional extraction of heat. In some embodiments, fluid is circulated, returning to the distal side of top plate 110 after cooling. In other embodiments, heated fluid is carried away and replaced by new fluid at the distal side of cooling element 120. As a result, heat-generating structure 102 may be cooled.

FIGS. 1E-IF depict an embodiment of active MEMS cooling system 100 including centrally anchored cooling element 120 in which the cooling element is driven out-of-phase. More specifically, sections of cooling element 120 on opposite sides of anchor 160 (and thus on opposite sides of the central region of cooling element 120 that is supported by anchor 160) are driven to vibrate out-of-phase. In some embodiments, sections of cooling element 120 on opposite sides of anchor 160 are driven at or near one hundred and eighty degrees out-of-phase. Thus, one section of cooling element 120 vibrates toward top plate 110, while the other section of cooling element 120 vibrates toward orifice plate 130/heat-generating structure 102. Thus, one section of cooling element 120 may carry out an upstroke, while the other section performs a downstroke. Thus, fluid traveling at high speeds (e.g. speeds described with respect to in-phase operation) is alternately driven out of orifices 132 on opposing sides of anchor 160. Because fluid is driven through orifices 132 at high speeds, cooling system 100 may be viewed as a MEMs jet. The net movement of fluid is shown by unlabeled arrows in FIGS. 1E and 1F. However, the unlabeled arrows in FIGS. 1E and 1F are not intended to indicate the motion of fluid at a particular time. The motion between the positions shown in FIGS. 1E and 1F is repeated. Thus, cooling element 120 undergoes vibrational motion indicated in FIGS. 1A, 1E, and 1F, alternately drawing fluid through vent 112 from the distal side of top plate 110 into top chamber 140 for each side of cooling element 120; transferring fluid from each side of top chamber 140 to the corresponding side of bottom chamber 150; and pushing the fluid through orifices 132 on each side of anchor 160 and toward heat-generating structure 102. As discussed above, cooling element 120 is driven to vibrate at or near the structural resonant frequency of cooling element 120. Further, the structural resonant frequency of cooling element 120 is configured to align with the acoustic resonance of the chamber 140/150. The structural and acoustic resonant frequencies are generally chosen to be in the ultrasonic range. For example, the vibrational motion of cooling element 120 may be at the frequencies described for in-phase vibration. The structural resonant frequency of cooling element 120 is within ten percent of the acoustic resonant frequency of cooling system 100. In some embodiments, the structural resonant frequency of cooling element 120 is within five percent of the acoustic resonant frequency of cooling system 100. In some embodiments, the structural resonant frequency of cooling element 120 is within three percent of the acoustic resonant frequency of cooling system 100. Consequently, efficiency and flow rate may be enhanced. However, other frequencies may be used.

Fluid driven toward heat-generating structure 102 for out-of-phase vibration may move in a manner analogous to that described above for in-phase operation. Similarly, chimneys or other ducting (not shown) at the edges of cooling system 100 allow fluid to be carried away from heat-generating structure 102. In other embodiments, heated fluid may be transferred further from heat-generating structure 102 in another manner. The fluid may exchange the heat transferred from heat-generating structure 102 to another structure or to the ambient environment. Thus, fluid at the distal side of top plate 110 may remain relatively cool, allowing for the additional extraction of heat. In some embodiments, fluid is circulated, returning to the distal side of top plate 110 after cooling. In other embodiments, heated fluid is carried away and replaced by new fluid at the distal side of cooling element 120. As a result, heat-generating structure 102 may be cooled.

Although shown in the context of a uniform cooling clement in FIGS. 1A-1F, cooling system 100 may utilize cooling elements having different shapes. FIG. 1G depicts an embodiment of engineered cooling element 120′ having a tailored geometry and usable in a cooling system such as cooling system 100. Cooling element 120′ includes an anchored region 122 and cantilevered arms 123. Anchored region 122 is supported (e.g. held in place) in cooling system 100 by anchor 160. Cantilevered arms 123 undergo vibrational motion in response to cooling element 120′ being actuated. Each cantilevered arm 123 includes step region 124, extension region 126 and outer region 128. In the embodiment shown in FIG. 1G, anchored region 122 is centrally located. Step region 124 extends outward from anchored region 122. Extension region 126 extends outward from step region 124. Outer region 128 extends outward from extension region 126. In other embodiments, anchored region 122 may be at one edge of the actuator and outer region 128 at the opposing edge. In such embodiments, the actuator is edge anchored.

Extension region 126 has a thickness (extension thickness) that is less than the thickness of step region 124 (step thickness) and less than the thickness of outer region 128 (outer thickness). Thus, extension region 126 may be viewed as recessed. Extension region 126 may also be seen as providing a larger bottom chamber 150. In some embodiments, the outer thickness of outer region 128 is the same as the step thickness of step region 124. In some embodiments, the outer thickness of outer region 128 is different from the step thickness of step region 124. In some embodiments, outer region 128 and step region 124 each have a thickness of at least three hundred twenty micrometers and not more than three hundred and sixty micrometers. In some embodiments, the outer thickness is at least fifty micrometers and not more than two hundred micrometers thicker than the extension thickness. Stated differently, the step (difference in step thickness and extension thickness) is at least fifty micrometers and not more than two hundred micrometers. In some embodiments, the outer step (difference in outer thickness and extension thickness) is at least fifty micrometers and not more than two hundred micrometers. Outer region 128 may have a width, q, of at least one hundred micrometers and not more than three hundred micrometers. Extension region 126 has a length, e, extending outward from the step region of at least 0.5 millimeter and not more than 1.5 millimeters in some embodiments. In some embodiments, outer region 128 has a higher mass per unit length in the direction from anchored region 122 than extension region 126. This difference in mass may be due to the larger size of outer region 128, a difference in density between portions of cooling clement 120, and/or another mechanism.

Use of engineered cooling element 120′ may further improve efficiency of cooling system 100. Extension region 126 is thinner than step region 124 and outer region 128. This results in a cavity in the bottom of cooling element 120′ corresponding to extension region 126. The presence of this cavity aids in improving the efficiency of cooling system 100. Each cantilevered arm 123 vibrates towards top plate 110 in an upstroke and away from top plate 110 in a downstroke. When a cantilevered arm 123 moves toward top plate 110, higher pressure fluid in top chamber 140 resists the motion of cantilevered arm 123. Furthermore, suction in bottom chamber 150 also resists the upward motion of cantilevered arm 123 during the upstroke. In the downstroke of cantilevered arm 123, increased pressure in the bottom chamber 150 and suction in top chamber 140 resist the downward motion of cantilevered arm 123. However, the presence of the cavity in cantilevered arm 123 corresponding to extension region 126 mitigates the suction in bottom chamber 150 during an upstroke. The cavity also reduces the increase in pressure in bottom chamber 150 during a downstroke. Because the suction and pressure increase are reduced in magnitude, cantilevered arms 123 may more readily move through the fluid. This may be achieved while substantially maintaining a higher pressure in top chamber 140, which drives the fluid flow through cooling system 100. Moreover, the presence of outer region 128 may improve the ability of cantilevered arm 123 to move through the fluid being driven through cooling system 100. Outer region 128 has a higher mass per unit length and thus a higher momentum. Consequently, outer region 128 may improve the ability of cantilevered arms 123 to move through the fluid being driven through cooling system 100. The magnitude of the deflection of cantilevered arm 123 may also be increased. These benefits may be achieved while maintaining the stiffness of cantilevered arms 123 through the use of thicker step region 124. Further, the larger thickness of outer region 128 may aid in pinching off flow at the bottom of a downstroke. Thus, the ability of cooling element 120′ to provide a valve preventing backflow through orifices 132 may be improved. Thus, performance of cooling system 100 employing cooling element 120′ may be improved.

Further, cooling elements used in cooling system 100 may have different structures and/or be mounted differently than depicted in FIGS. 1A-1G. In some embodiments, the cooling element may have rounded corners and/or rounded ends but still be anchored along a central axis such that cantilevered arms vibrate. The cooling element may be anchored only at its central region such that the regions surrounding the anchor vibrate in a manner analogous to a jellyfish or the opening/closing of an umbrella. In some such embodiments, the cooling element may be circular or elliptical in shape. In some embodiments, the anchor may include apertures through which fluid may flow. Such an anchor may be utilized for the cooling element being anchored at its top (e.g. to the top plate). Although not indicated in FIGS. 1A-1G, the piezoelectric material utilized in driving the cooling element may have various locations and/or configurations. For example, the piezoelectric material may be embedded in the cooling element, affixed to one side of the cooling element (or cantilevered arm(s)), may occupy some or all of the cantilevered arms, and/or may have a location that is close to or distal from the anchored region. In some embodiments, cooling elements that are not centrally anchored may be used. For example, a pair of cooling elements that have offset apertures, that are anchored at their ends (or all edges), and which vibrate out of phase may be used. Thus, various additional configurations of cooling element 120 and/or 120′, anchor 160, and/or other portions of cooling system 100 may be used.

Using the cooling system 100 actuated for in-phase vibration or out-of-phase vibration of cooling element 120 and/or 120′, fluid drawn in through vent 112 and driven through orifices 132 may efficiently dissipate heat from heat-generating structure 102. Stated differently, heat transfer between heat-generating structure 102 and the moving fluid is improved. Because the heat-generating structure is more efficiently cooled, the corresponding integrated circuit may be run at higher speed and/or power for longer times. For example, if the heat-generating structure corresponds to a high-speed processor, such a processor may be run for longer times before throttling. Thus, performance of a device utilizing cooling system 100 may be improved. Further, cooling system 100 may be a MEMS device. Consequently, cooling systems 100 may be suitable for use in smaller and/or mobile devices, such as smart phones, other mobile phones, virtual reality headsets, tablets, two-in-one computers, wearables and handheld games, in which limited space is available. Performance of such devices may thus be improved. Because cooling element 120/120′ may be vibrated at frequencies of 15 kHz or more, users may not hear any noise associated with actuation of cooling elements. If driven at or near structural and/or acoustic resonant frequencies, the power used in operating cooling systems may be significantly reduced. Cooling element 120/120′ may not physically contact top plate 110 or orifice plate 130 during vibration in normal operation. Thus, resonance of cooling element 120/120′ may be more readily maintained. Issues related to moving away from resonance may be mitigated or avoided through the use of pressure differentials and fluid flow as discussed above. The benefits of improved, quiet cooling may be achieved with limited additional power. Further, out-of-phase vibration of cooling element 120/120′ allows the position of the center of mass of cooling element 120/120′ to remain more stable. Although a torque is exerted on cooling element 120/120′, the force due to the motion of the center of mass is reduced or eliminated. As a result, vibrations due to the motion of cooling element 120/120′ may be reduced. Moreover, efficiency of cooling system 100 may be improved through the use of out-of-phase vibrational motion for the two sides of cooling element 120/120′. Consequently, performance of devices incorporating the cooling system 100 may be improved. Further, cooling system 100 may be usable in other applications (e.g. with or without heat-generating structure 102) in which high fluid flows and/or velocities are desired.

In addition, cooling system 100 may have a high back pressure. Back pressure is a measure of the resistance to a fluid flow driven through a system. The back pressure may be considered to be the pressure at which flow through the system goes to zero. Stated differently, the back pressure may be the pressure at which the system can no longer drive fluid flow. Cooling system 100 may have a high back pressure. For example, in some embodiments, the back pressure of cooling system 100 may be on the order of 2 kPa. Depending upon the geometry and fluid used, higher back pressures may be possible. For example, the back pressure of cooling system 100 may be on the order of 6-11 kPa in some embodiments. In some embodiments, the back pressure of cooling system 100 may be 8-10 kPa. As such, system 100 may be capable of driving fluid, and cooling heat-generating structure 102, even at higher pressures (e.g., 2 kPa, 6 kPa, or up to 8-10 kPa).

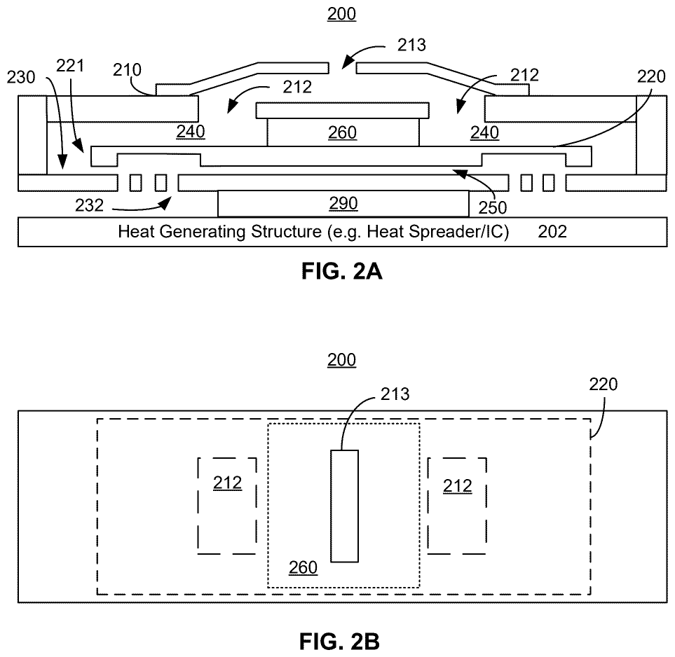

FIGS. 2A-2B depict an embodiment of active MEMS cooling system 200 including a top centrally anchored cooling element. FIG. 2A depicts a side view of cooling system 200 in a neutral position. FIG. 2B depicts a top view of cooling system 200. FIGS. 2A-2B are not to scale. For simplicity, only portions of cooling system 200 are shown. Referring to FIGS. 2A-2B, cooling system 200 is analogous to cooling system 100. Consequently, analogous components have similar labels. For example, cooling system 200 is used in conjunction with heat-generating structure 202, which is analogous to heat-generating structure 102.

Cooling system 200 includes top plate 210 having vents 212, cooling element 220 having tip 221, orifice plate 230 including orifices 232, top chamber 240 having a gap, bottom chamber 250 having a gap, flow chamber 240/250, and anchor (i.e. support structure) 260 that are analogous to top plate 110 having vent 112, cooling element 120 having tip 121, orifice plate 130 including orifices 132, top chamber 140 having gap 142, bottom chamber 150 having gap 152, flow chamber 140/150, and anchor (i.e. support structure) 160, respectively. Also shown is pedestal 290 analogous to pedestal 190. Thus, cooling element 220 is centrally supported by anchor 260 such that at least a portion of the perimeter of cooling element 220 is free to vibrate. In some embodiments, anchor 260 extends along the axis of cooling clement 220. In other embodiments, anchor 260 is only near the center portion of cooling element 220. Although not explicitly labeled in FIGS. 2A and 2B, cooling element 220 includes an anchored region and cantilevered arms including step region, extension region, and outer regions analogous to anchored region 122, cantilevered arms 123, step region 124, extension region 126, and outer region 128 of cooling element 120′. In some embodiments, cantilevered arms of cooling element 220 are driven in-phase. In some embodiments, cantilevered arms of cooling element 220 are driven out-of-phase. In some embodiments, a simple cooling element, such as cooling element 120, may be used. Further, although cavities analogous to cavities 134 and 135 are not depicted in cooling system 200, such cavities may be present.

Anchor 260 supports cooling element 220 from above. Thus, cooling element 220 is suspended from anchor 260. Anchor 260 is suspended from top plate 210. Top plate 210 includes vent 213. Vents 212 on the sides of anchor 260 provide a path for fluid to flow into sides of chamber 240.

As discussed above with respect to cooling system 100, cooling clement 220 may be driven to vibrate at or near the structural resonant frequency of cooling element 220. Further, the structural resonant frequency of cooling element 220 may be configured to align with the acoustic resonance of chamber 240/250. The structural and acoustic resonant frequencies are generally chosen to be in the ultrasonic range. For example, the vibrational motion of cooling element 220 may be at the frequencies described with respect to cooling system 100. Consequently, efficiency and flow rate may be enhanced. However, other frequencies may be used.

Cooling system 200 operates in an analogous manner to cooling system 100. Cooling system 200 thus shares the benefits of cooling system 100. Thus, performance of a device employing cooling system 200 may be improved. In addition, suspending cooling element 220 from anchor 260 may further enhance performance. In particular, vibrations in cooling system 200 that may affect other cooling cells (not shown) may be reduced. For example, less vibration may be induced in top plate 210 due to the motion of cooling element 220. Consequently, cross talk between cooling system 200 and other cooling systems (e.g. other cells) or other portions of the device incorporating cooling system 200 may be reduced. Thus, performance may be further enhanced.

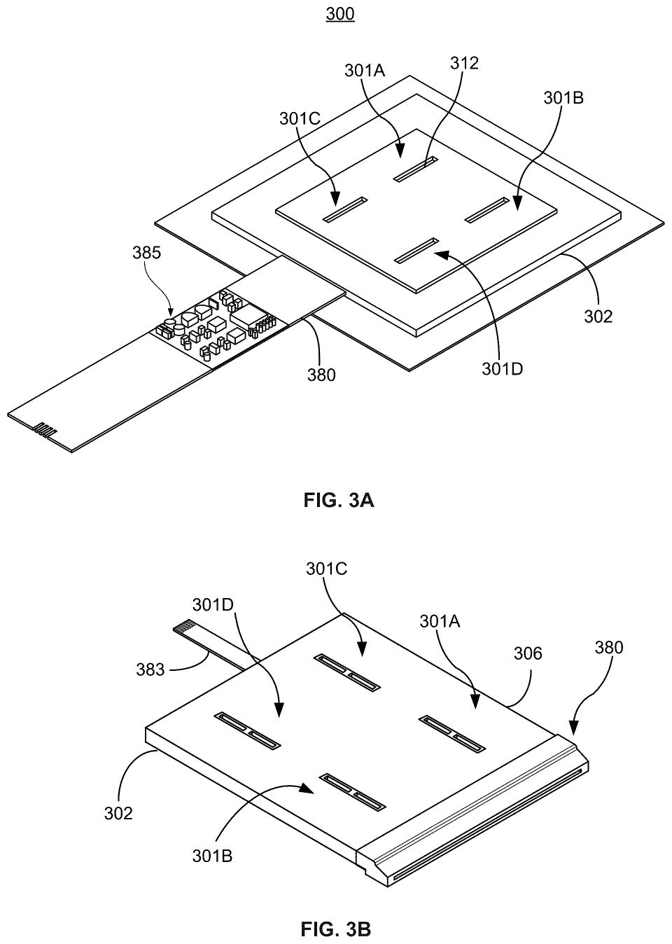

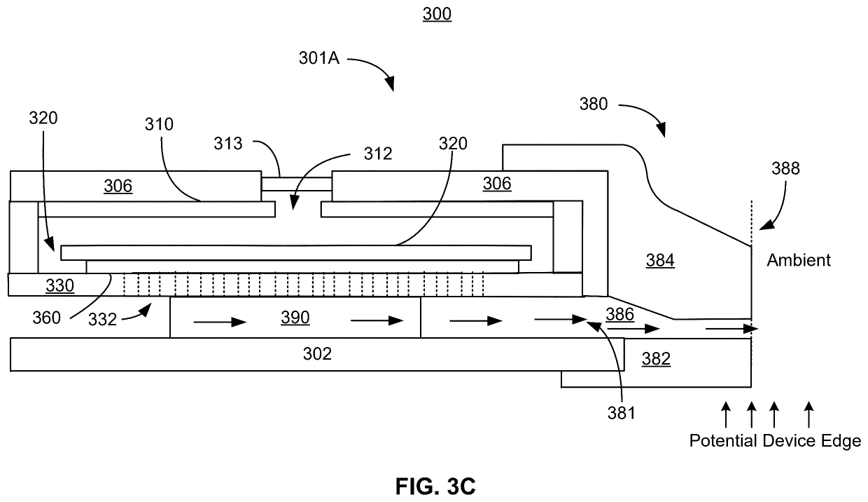

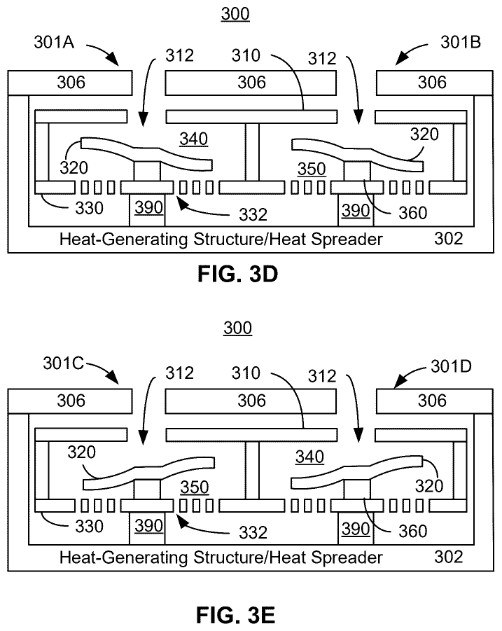

FIGS. 3A-3E depict an embodiment of active MEMS cooling system 300 including multiple cooling cells configured as a module termed a tile, or array. FIG. 3A depicts a perspective view with spout 380 removed. FIG. 3B depicts active MEMS cooling system 300 with cover 306 and spout 380. FIG. 3C depicts a side view of a portion of cooling system 300. FIGS. 3D-3E depict side/cross-sectional views of cooling system 300. FIGS. 3A-3E are not to scale. Cooling system 300 includes four cooling cells 301A, 301B, 301C and 301D (collectively or generically 301), which are analogous to one or more of cooling systems described herein. More specifically, cooling cells 301 are analogous to cooling system 100 and/or 200. Tile 300 thus includes four cooling cells 301 (i.e. four MEMS jets). Although four cooling cells 301 in a 2×2 configuration are shown, in some embodiments another number and/or another configuration of cooling cells 301 might be employed. In the embodiment shown, cooling cells 301 include shared top plate 310 having apertures 312, cooling elements 320, shared orifice plate 330 including orifices 332, top chambers 340, bottom chambers 350, anchors (support structures) 360, and pedestals 390 that are analogous to top plate 110 having apertures 112, cooling element 120, orifice plate 130 having orifices 132, top chamber 140, bottom chamber 150, anchor 160, and pedestal 190. In some embodiments, cooling cells 301 may be fabricated together and separated, for example by cutting through top plate 310, side walls between cooling cells 301, and orifice plate 330. Thus, although described in the context of a shared top plate 310 and shared orifice plate 330, after fabrication cooling cells 301 may be separated. In some embodiments, tabs (not shown) and/or other structures such as anchors 360 may connect cooling cells 301. Although not shown, cooling cells 301 may have cavities analogous to cavities 114, 134, and/or 135. Further, tile 300 includes heat-generating structure (termed a heat spreader hereinafter) 302 (e.g. a heat sink, a heat spreader, and/or other structure) that also has sidewalls, or fencing, in the embodiment shown. Cover 306 having apertures therein is also shown. In some embodiments, a dust filter (not shown) may be provided for the apertures. In such embodiments, dust may be less likely to reach the interior of cooling system 300. In some embodiments, a water tight, air porous membrane may be provided for the apertures. Heat spreader 302, cover 306, and spout 380 may be part of an integrated tile 300 as shown or may be separate from tile 300 in other embodiments. Heat spreader 302 and cover plate 306 may direct fluid flow outside of cooling cells 301, provide mechanical stability, and/or provide protection. Electrical connection to cooling cells 301 is provided via flex connector 380 (not shown in FIGS. 3C-3E) which may house drive electronics 385. Cooling elements 320 are driven out-of-phase (i.e. in a manner analogous to a see-saw). Further, as can be seen in FIGS. 3D-3E cooling element 320 in one cell is driven out-of-phase with cooling clement(s) 320 in adjacent cell(s). Cooling elements 320 in a column are driven out-of-phase. Thus, cooling element 320 in cell 301A is out-of-phase with cooling element 320 in cell 301C. Similarly, cooling element 320 in cell 301B is out-of-phase with cooling element 320 in cell 301D. By driving cooling elements 320 out-of-phase, vibrations in cooling system 300 may be reduced. Cooling elements 320 may be driven in another manner in some embodiments. For example, cooling elements 301A and 301C may be driven in-phase but out-of-phase with cooling element 301B and 301D.

Cooling system 300 may also include spout 380 having dissipation region 386 therein. Thus, cooling system 300 including top cover 306 and heat spreader 302 may have a total thickness not exceeding four millimeters. In some embodiments, the height of cooling system 300 does not exceed 3.5 millimeters. In some embodiments, the height of cooling system 300 does not exceed 3 millimeters. In some embodiments, cooling system 300 has a height of at least 2 millimeters. Spout 380 includes a housing having bottom 382 and top 384, entrance 381 and exit 386. Entrance 381 is fluidically coupled with orifices 332 (i.e. egresses from flow chamber 340/350). The direction of fluid flow from flow chamber 340/350 may be seen by the unlabeled arrows in FIG. 3C. Spout 380 operates to smooth pulsations in the pressure waves generated by cooling elements 320. Because cooling elements 320 vibrate, the flow of fluid pulsates. Thus, the pressure of the fluid also pulsates between higher and lower pressures. Flow may also exit orifices 332 and travel through the jet channel in pulses. The pressure within flow chamber 340/350 and the jet channel is higher than the pressure of the ambient region. The fluid exits the jet channel and enters spout 380 at entrance 381. The fluid travels through dissipation region 386 and to exit 388. The pulsating pressure in the fluid is dissipated in dissipation region 384. Stated differently, the pulsations in pressure may be attenuated such that the pressure equilibrates and approaches (or reaches) the ambient pressure of the ambient region outside of system 300. In some embodiments, therefore, the pressure of the fluid at exit 388 of spout 380 matches or substantially the boundary conditions for the pressure of the ambient. In some embodiments of cooling system 300, spout 380 may be omitted. Also shown in FIG. 3C is optional dust guard 313. Dust guard 313 may be a MERV 14 or other analogous filter used to reduce or eliminate small particles from entering cooling system 300. Further, although cavities analogous to cavities 134 are not depicted in cooling system 300, such cavities may be present.

Cooling cells 301 of cooling system 300 function in an analogous manner to cooling system(s) 100, 200, and/or an analogous cooling system. Consequently, the benefits described herein may be shared by cooling system 300. Because cooling elements in nearby cells are driven out-of-phase, vibrations in cooling system 300 may be reduced. Because multiple cooling cells 301 are used, cooling system 300 may enjoy enhanced cooling capabilities. Further, multiples of individual cooling cells 301 and/or cooling system 300 may be combined in various fashions to obtain the desired footprint of cooling cells.

The cooling systems and methods are described in the context of various features. The features of cooling systems and method(s) described herein may be combined in various ways not explicitly depicted. For example, cavities 134 and/or 135 may be omitted, cavities in top plate 110 may be present, cooling element 120 may be used in cooling system 200, and/or various features of systems 400, 500, 600, 700, 800, 900, and/or 1000 may be combined in manners not explicitly shown.

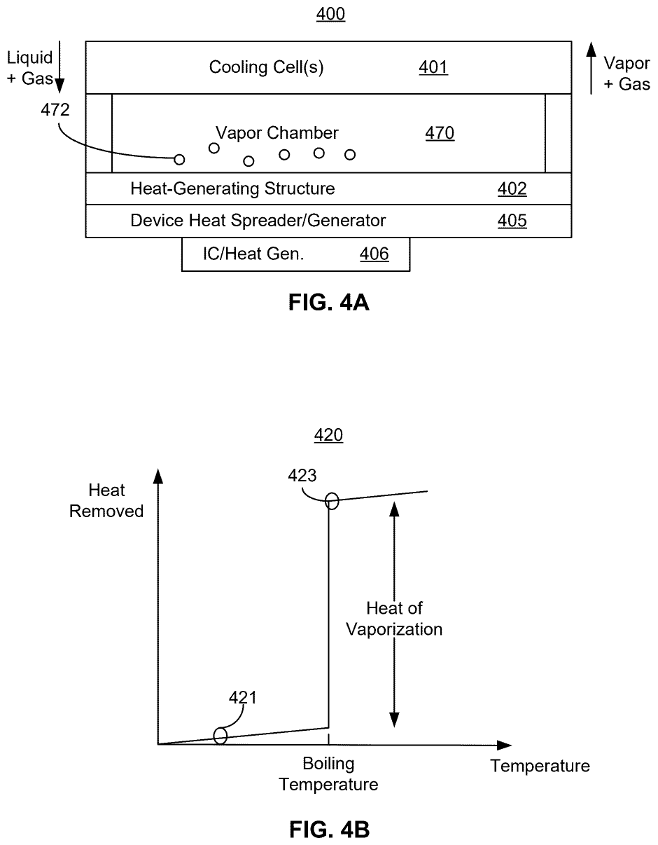

FIGS. 4A-4B depict an embodiment of an active MEMS cooling system 400 utilizing a phase change and graph 420 indicating the performance. More specifically, FIG. 4A depicts MEMS cooling system 400, while FIG. 4B depicts graph 420. MEMS cooling system 400 is a multi-phase cooling system. The fluid(s) driven through MEMS cooling system 400 may undergo one or more phase changes (e.g. a liquid-vapor phase change) during use. Also shown in FIG. 4A are a device heat spreader/generator 405 and device heat-generating structure 406. Cooling system 400 may be thermally coupled (e.g. via thermal conduction) and/or physically coupled with device components 405 and/or 406. For example, device heat spreader/generator 405 may be a heat spreader, vapor chamber, TEC (Thermo electric coldplate) or component such as an integrated circuit (IC) or battery. Device heat-generating structure 406 may be an IC, such as a central processing unit (CPU) and/or graphics processing unit (GPU). Other device components 405 and/or 406 that generate heat, spread heat, or are desired to be cooled for other reasons may be present and thermally coupled with active MEMS cooling system 400. In some embodiments, heat-generating structure 402 may be omitted and cooling cell(s) 401 coupled directly to device heat spreader 405 or device IC/generating structure 406. In such embodiments, heat may be transferred directly from component(s) 405 and/or 406 to the mixture.

Active MEMS cooling system 400 includes one or more cooling cells 401 and heat-generating structure 402 that are analogous to cooling system(s) 100, 200, and/or 300, cooling cell(s) 301, and heat-generating structures 102, 202, and/or 302. Thus, cooling cell 401 may include an active element analogous to cooling element(s) 120, 120′, 220, and/or 320 and a chamber analogous to chambers 140/150, 240/250, and/or 340/350. The active element is configured to undergo vibrational motion when activated. In such embodiments, cooling systems used in cooling cell(s) 401 may be configured for high temperatures. For example, the electronics 385 and/or flex connector 383 (depicted in FIG. 3A) may be reconfigured to sustain higher temperatures. Similarly, cooling element(s) 120 and/or 120′ may be formed of a metal (e.g. Ti or a Ti alloy) or other material which can both undergo vibrations at the desired frequency and withstand the temperature(s) at or around the temperature of the phase change(s) used in MEMS cooling system 400.

In some embodiments, cooling cells 401 are configured to drive a mixture of fluids (e.g. a gas such as air and a liquid such as water and/or alcohol) through active MEMS cooling system 400. In some embodiments, cooling cells 401 drive a mixture of gas (e.g. air) and vapor (e.g. water and/or alcohol vapor) away from heat-generating structure 402. In such embodiments, a portion of the liquid in MEMS cooling system 400 has already undergone a phase change from liquid to vapor in response to exposure to the heat from heat-generating structure 402 before being driven through the chamber(s) in cooling cell(s) 401 by vibrational motion of the active element. Thus, the vibrational motion of the active element(s) draws the mixture of liquid vapor and gas from proximate to heat-generating structure 402 through the chamber of cooling cell(s) 401. In some embodiments, cooling cells 401 drive a mixture of gas (e.g. air) and liquid (e.g. water and/or alcohol droplets) toward heat-generating structure 402. In such embodiments, a portion of the liquid undergoes a phase change from liquid to vapor after being driven through the chamber(s) of cooling cell(s) 401. The vibrational motion of the active clement(s) draws the mixture of liquid droplets and gas through cooling cell(s) 401 to being proximate to heat-generating structure 402. Thus, the phase (liquid or vapor) of the liquid in the mixture driven through the chamber(s) of cooling cell(s) 401 may depend upon the direction which cooling cell(s) 401 drive the mixture. This may be achieved by choosing the appropriate orientation of cooling cells 401 (e.g. the locations of the inlet and jet channel).

Active MEMS cooling system 400 also includes vapor chamber 470 between cooling cell(s) 401 and heat-generating structure 402. Thus, cooling cell(s) 401, vapor chamber 470, and heat-generating structure 402 may form an integrated cooling system. In some embodiments, the liquid to vapor phase change occurs in vapor chamber 470. This phase change may occur proximate to or at a surface of heat-generating structure 402 within vapor chamber 470.

In some embodiments, the liquid used in active MEMS cooling system 400 is water. In some embodiments, the liquid used in active MEMS cooling system 400 is alcohol. In some embodiments using alcohol, MEMS cooling system 400 is a closed system. In some embodiments, a mixture of water and alcohol may be used. In some embodiments, additional and/or other liquids may be used. The liquid(s) used in cooling system 400 may be selected such that the boiling temperature of the mixture is consistent with using a phase change for cooling heat-generating structure 402, and thus, device heat spreader/generator 405 and/or device IC/heat-generating structure 406. For example, if the operating temperature of device IC/heat-generating structure 406 is such that heat-generating structure 402 has an operating temperature of eighty-five degrees Celsius, then the boiling temperature of the liquid used in MEMS cooling system 400 may be desired to be not more than eighty-five degrees Celsius (e.g. eighty to eighty-three degrees Celsius, eighty to eighty-five degrees Celsius, eighty to ninety degrees Celsius, seventy-five to eighty degrees Celsius). The boiling temperature of the liquid is also desired to be well above the quiescent temperature of heat-generating structure 402 (e.g. well above room temperature). For example, in some embodiments, the boiling temperature of the liquid is desired to be at least sixty degrees Celsius or at least seventy degrees Celsius.

In operation, the active element(s) (not shown in FIG. 4A) within chamber(s) (not shown in FIG. 4A) of cooling cell(s) 401 are actuated to vibrate. The active element(s) may be activated based on the temperature of heat-generating structure 402. This temperature may be directly measured (e.g. by a thermistor within MEMS cooling system 400) or indirectly determined (e.g. by the length of time device IC/heat-generating structure 406 has been turned on). In some embodiments, cooling cell(s) 401 are activated such that liquid vapor and gas are drawn from vapor chamber 470 (e.g. proximate to heat-generating structure 402) into cooling cells 401. In such embodiments, the liquid enters vapor chamber 470 from another region and undergoes a liquid to vapor phase change in response to exposure to the heat of heat-generating structure 402. The heated vapor and gas are driven from vapor chamber 470, through the chamber(s) of cooling cell(s) 401 and out of cooling cells 401/cooling system 400. In some embodiments, cooling cell(s) 401 are activated such that liquid (e.g. droplets) and gas are driven into vapor chamber 470 (e.g. proximate to heat-generating structure 402). The liquid undergoes a liquid to vapor phase change in response to exposure to the heat of heat-generating structure 402. The heated vapor and gas exit vapor chamber 470 through another region.

In either case, MEMS cooling system 400 transfers heat from heat-generating structure 402 to the mixture of liquid (vapor/droplets) and gas. Because the liquid undergoes a phase change from liquid to vapor, the amount of heat extracted may be significant. Graph 420 of FIG. 4B indicates the amount of heat removed (i.e. transferred to the mixture of liquid and gas) based on temperature of the mixture for a flow driven by cooling cell(s) 401. For temperatures below the boiling temperature, heat is removed at a moderate rate (e.g. indicated by oval 421 below the boiling temperature) by the flow of the mixture. However, when the boiling temperature of the liquid is reached, at least some of the liquid in vapor chamber 470 changes phase from liquid to vapor. The heat of vaporization of a liquid is generally relatively large in comparison to the specific heat of a liquid or gas. Thus, the amount of heat transferred increased very rapidly with little or no change in temperature of the fluid. Above the boiling temperature (e.g. where the liquid has been changed to vapor and the mixture may be gascous), the heat removed from heat-generating structure 402 is again more moderate. Thus, at temperature near the boiling temperature, the liquid-vapor transition may be used to very efficiently cool heat-generating structure 402 and thus device components 405 and/or 406.

The temperature at which the liquid changes phase to a vapor depends not only upon the liquid used, but also on the pressure in vapor chamber 470 in which the phase change occurs. For example, if the liquid used is water, then the boiling temperature of the liquid may be approximately one hundred degrees Celsius (e.g., at atmospheric pressure at sea level). In some embodiments, a mixture of water and alcohol (e.g. ninety percent water and ten percent alcohol such as ethanol) may be used. A ten percent alcohol solution may have a boiling temperature of approximately ninety-two degrees Celsius. Higher concentrations of alcohol may be used to further decrease the boiling temperature. Ethanol has a boiling temperature of approximately seventy-eight degrees Celsius. In some embodiments, pure alcohol may be used, for example if a closed system is used. In some embodiments, other organic liquids having other (e.g., lower) boiling temperatures may be used in addition to or in lieu of water and/or alcohol. Thus, the temperature at which cooling system 400 may be used to manage heat may be tailored.

In some embodiments, the pressure in vapor chamber 470 may be used to further reduce the boiling temperature of the liquid undergoing the phase change. In some embodiments, therefore, the pressure in vapor chamber 470 is controlled by cooling cell(s) 401. In such embodiments, vibrational motion of the active element(s) in cooling cell(s) 401 may draw the mixture of liquid vapor and gas from vapor chamber 470 into cooling cell(s) 401. This may reduce the pressure in vapor chamber 470. A reduction in pressure generally results in a reduction in the boiling temperature of the liquid. As a result, the liquid in vapor chamber 470 may undergo a liquid to vapor phase change at a reduced temperature. For example suppose the mixture of water and alcohol has a boiling temperature of ninety degrees Celsius. A reduction in pressure of two kiloPascals (2 kPa) may result in a one degree Celsius decrease in boiling temperature. Cooling cell(s) 401 may be configured to provide up to a 10 kPa reduction in pressure in vapor chamber 470. In such embodiments, the boiling temperature of the liquid in vapor chamber 470 may be reduced to approximately eight-five degrees Celsius. In some embodiments, the vibrational motion of the active elements reduces the pressure by at least 1 kPa, at least 2 kPa, at least 5 kPa, at least 7 kPa, at least 9 kPa, or at least 10 kPa. In some embodiments, the pressure is reduced by not more than 12 kPa (e.g. nominally 10 kPa). In some embodiments, the reduction in pressure may have other values (e.g. at least 15 kPa, at least 20 kPa). This reduction in boiling temperature may be desirable to cool device component(s) 405 and/or 406 at more moderate temperatures (e.g. below one hundred degrees Celsius).

Thus, using MEMS cooling system 400, significant amounts of heat may be removed from heat-generating structure 402, therefore, device structures 405 and 406. Because MEMS cooling system 400 utilizes the change in phase of the liquid portion of the mixture, a large amount of heat may be removed from heat-generating structure 402 (e.g., a heat spreader) and, therefore, device component(s) 405 and/or 406 that are thermally connected to heat-generating structure 402. Consequently, thermal management may be greatly improved. In addition, the flow rate, chamber pressure, and liquid-vapor transition temperature may be tailored using cooling cell(s) 401 of MEMS cooling system 400. Further, MEMS cooling system 400 is thin. For example, the thickness of MEMS system 400 may be nominally three millimeters or less in some embodiments. In some embodiments, MEMS cooling system 400 may be not more than five millimeters thick. In some embodiments, MEMS cooling system 400 may be not more than four millimeters thick or not more than three and one-half millimeters thick. In some embodiments, MEMS cooling system 400 is at least two millimeters thick. Thus, in addition to providing significant cooling, MEMS cooling system 400 may have a low profile. Thus, MEMS cooling system 400 may be used in thin computing devices, in data centers (e.g. for cooling of components in racks), and/or other devices in which little space is available for cooling systems.

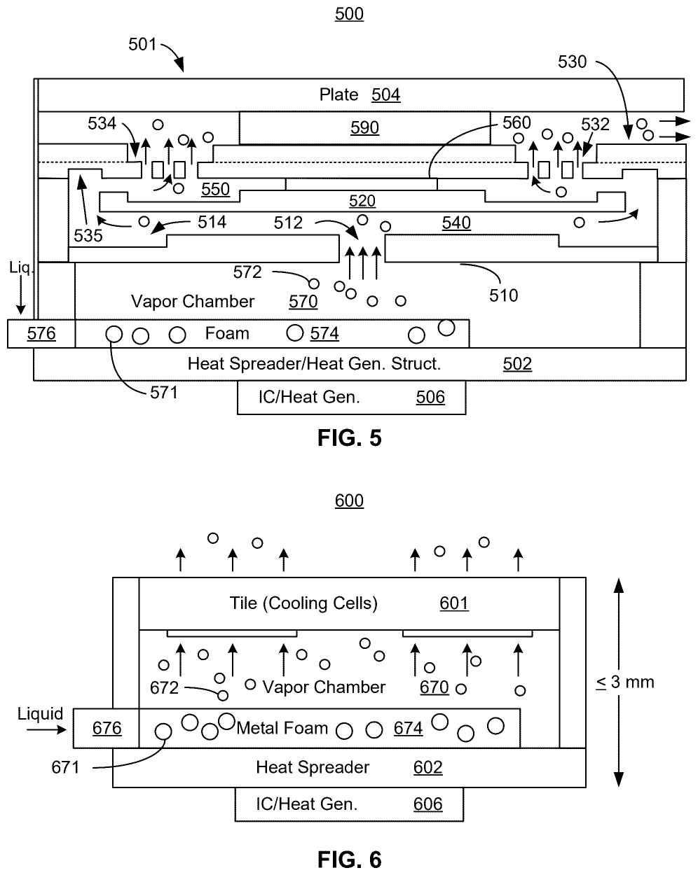

FIG. 5 depicts an embodiment of active MEMS cooling system 500 utilizing a phase change. Cooling system 500 is analogous to cooling system 400 as well as cooling systems 100, 200, and 300. Thus, analogous components are labeled similarly. MEMS cooling system 500 includes cooling cell 501 coupled with heat-generating structure 502 and vapor chamber 570 that are analogous to cooling cell(s) 401, heat-generating structure 402, and vapor chamber 470, respectively. Also shown is device IC/heat-generating structure 506. In some embodiments, a heat spreader analogous to device heat spreader 405 may be present. Although not shown, cooling cell 501 may have a spout and cover analogous to spout 380 and cover 306. Cooling cell 501 includes top plate 510 having vent(s) 512, active element 520, orifice plate 530 including orifices 532, top chamber 540, bottom chambers 550 (together forming chamber 540/550), anchor (support structure) 560, and pedestal 590 that are analogous to top plate 110 having apertures 112, cooling element 120, orifice plate 130 having orifices 132, top chamber 140, bottom chamber 150, anchor 160, and pedestal 190. In some embodiments, a dust filter (not shown) may be provided for the aperture(s) 512. In the embodiment shown, top plate 510 includes cavities 514. Such cavities may facilitate the vibrational motion of active element 520. Cooling cell 501 also includes plate 504 to which pedestal 590 is coupled. Thus, a jet channel may be formed between orifice plate 530 and plate 504. Although orifices 532 are shown in orifice plate 530, in some embodiments, orifices may be at the sidewalls of cooling cell 501.

Cooling cell 501 is indicated as oriented differently from cooling cell 100. More specifically, cooling cell 501 is configured with aperture(s) 512 closer to heat-generating structure 502 than orifices 532. Cooling cell 501 may be considered to be inverted as compared to cooling cell 100.

Vapor chamber 570 is between heat-generating structure 502 and cooling cell 501. Vapor chamber 570 also includes high-temperature foam 574 thermally coupled (e.g. via thermal conduction) to heat-generating structure 502. In some embodiments, a metal foam, such as a copper mesh, may be used for high-temperature foam 574. For example, a copper mesh having a thickness of at least one hundred micrometers and not more than five hundred micrometers (e.g., not more than three hundred micrometers) may be used. In some embodiments, high-temperature foam 574 may be replaced by another component having analogous functions. High-temperature foam 574 is coupled with liquid source 576. In some embodiments, liquid source 576 may be a liquid reservoir. In some embodiments, liquid source 576 may be a device such as a sponge fluidically coupled with a liquid reservoir or other component (e.g. a chiller in a closed system) from which cool liquid may be provided. High-temperature foam 574 is also thermally coupled (e.g. via thermal conduction) and may be physically coupled to heat-generating structure 502. High-temperature foam 574 takes up liquid from liquid source 576. For example, high-temperature foam 574 may wick up liquid from liquid source 576. However, high-temperature foam 574 is also configured such that liquid does not pool elsewhere on heat-generating structure 502. In some embodiments, the high-temperature foam 574 is at least one hundred micrometers thick and not more than three hundred micrometers thick. The amount of liquid is controlled by the wicking action of high-temperature foam 574. Thus, liquid may remain in high-temperature foam 574, rather than spilling onto heat-generating structure 502 in regions where no high-temperature foam 574 resides. Liquid within high-temperature foam 574 is indicated by liquid 571. In some embodiments, liquid 571 may be considered to be liquid droplets. In addition, a small amount of liquid (not explicitly shown but may be considered represented by liquid 571) may collect on the heat spreader 502.

In operation, liquid in liquid source 576 is taken up by high-temperature foam 574. High-temperature foam 574 may act as a wick, allowing liquid to remain in high-temperature foam 574 without overflowing from liquid source 576 (e.g., a sponge) or high-temperature foam 574 onto the heat-generating structure 502. In addition, cooling cell 501 may be activated (e.g. based on temperature and/or time of operation of device IC/heat-generating structure 506). The amount of liquid that is taken up by high-temperature foam 574 depends in part on the pressure in vapor chamber 570. Activating cooling cell 501 to drive fluid (e.g. the mixture including vapor 572 and a gas such as air) through the MEMS cooling system 500 reduces the pressure in vapor chamber 570. The reduction in the pressure in vapor chamber 570 increases the amount of liquid moving from liquid 576 to high-temperature foam 574. Thus, the amount of liquid transferred from liquid source 576 to high-temperature foam 574 may be controlled by the high-temperature foam 574 selected and the pressure in vapor chamber 570 induced by activation of cooling cell 501.

Liquid 571 in high-temperature foam 574 is exposed to heat from, e.g., heat-generating structure 502 and/or device IC/heat-generating structure 506. Heat is transferred from heat-generating structure 502 to the mixture (e.g. to liquid 571 in the high-temperature foam 574 and to a portion of the mixture in contact with heat-generating structure 502). For simple heating of a fluid (e.g. a liquid or a gas in the mixture) the amount of heat transferred to the fluid depends upon the specific heat of the fluid and the amount the temperature has been raised. When a phase change temperature (i.e. the boiling point) is reached, a large amount of energy may be transferred without an increase in temperature. At least some of liquid 571 in high-temperature foam 574 undergoes a phase change (i.e. from liquid to vapor) for heat-generating structure 502 being sufficiently hot. Further heating increases the temperature of the mixture (vapor 572 and gas that is not specifically shown). Thus, liquid vapor 572 is provided in vapor chamber 570.

Active element 520 is activated and undergoes vibrational motion (e.g. in phase or out-of-phase motion of the cantilevered sections not pinned to anchor 560). The vibrational motion draws a mixture of liquid vapor 572 and gas in vapor chamber 570 into chamber 540/550 via aperture(S) 512. The mixture is driven through chamber 540/550, through orifices 532, into the jet channel and out of cooling system 500. The flow of vapor and gas (i.e., the mixture) is indicated by the arrows and circles 572. Thus, heat generating structure 502 and/or other heat-generating structures may be efficiently cooled.

The vibrational motion of the active element 520 draws the vapor phase and the gas from vapor chamber 570 into chamber 540/550. In some such embodiments, the vibrational motion reduces a pressure in the vapor chamber below an inactive pressure corresponding to the active element being quiescent. For example, the vibrational motion reduces the pressure by at least 1 kPa, at least 2 kPa, at least 5 kPa, at least 7 kPa, at least 9 kPa, or at least 10 kPa. In some embodiments, the pressure is reduced by not more than 12 kPa (e.g. nominally 10 kPa). Other pressure reductions may be provided by activation of active element 520. Thus, for the reasons described herein, the vapor pressure and boiling temperature of liquid 571/572 are reduced. Consequently, activation of active element 520 not only may control the amount of liquid taken up by high-temperature foam 574, but may also control the boiling temperature of the liquid used.

Thus, using MEMS cooling system 500, significant amounts of heat may be removed from heat-generating structure 502, therefore, device structure 406. Because MEMS cooling system 500 utilizes the change in phase of the liquid portion of the mixture, a large amount of heat may be removed from heat-generating structure 502 (e.g., a heat spreader) and, therefore, device component(s) 406 that are thermally connected to heat-generating structure 502. Consequently, thermal management may be greatly improved. In addition, the flow rate, chamber pressure, amount of liquid taken up from liquid source 576, and/or liquid-vapor transition temperature may be tailored using cooling cell(s) 501 of MEMS cooling system 500. Further, MEMS cooling system 500 is thin. For example, the thickness of MEMS system 500 may be analogous to the thickness of MEMS cooling system 400. Thus, in addition to providing significant cooling, MEMS cooling system 500 may have a low profile. Thus, MEMS cooling system 500 may be used in thin computing devices, in data centers (e.g. for cooling of components in racks), and/or other devices in which little space is available for cooling systems. Performance of such system may, therefore, be improved.

FIG. 6 depicts an embodiment of active MEMS cooling system 600 utilizing a phase change. Cooling system 600 is analogous to cooling systems 400 and 500 as well as cooling systems 100, 200, and 300. Thus, analogous components are labeled similarly. MEMS cooling system 600 includes a tile 601 including multiple cooling cells coupled with heat-generating structure (e.g. heat spreader) 602, vapor chamber 670, metal foam 674, and liquid source 676 that are analogous to cooling cell(s) 401 and 501, heat-generating structure 402 and 502, vapor chamber 470 and 570, high-temperature foam 574, and liquid source 576, respectively. Also shown is device IC/heat-generating structure 606. In some embodiments, a heat spreader analogous to device heat spreader 405 may be present. Although not shown, tile 601 may have a spout and cover analogous to spout 380 and cover 306. In some embodiments, tile 601 may include two, four, six, or another number of cooling cells. Such cooling cells are analogous to cooling cell(s) 500 and/or 301 as well as cooling system 100 and/or 200. The cooling cells of tile 601 are oriented as cooling cells 501. Thus, the mixture of vapor 672 and gas enters the cooling cells of tile 601 from vapor chamber 670. Liquid enters vapor chamber 570 via liquid source 576 and metal foam 574.

Cooling system 600 operates in a manner analogous to cooling system 500. Thus, liquid is taken up by metal foam 674. The amount of liquid taken up as well as the boiling temperature of the liquid may be controlled at least in part by the pressure in vapor chamber 670. The pressure in vapor chamber 670 is controlled by vibration of active elements in cooling cells of tile 601. Liquid 671 in metal foam 674 may be heated due to exposure to heat from heat spreader 602. At least a portion of liquid 671 undergoes a phase change from liquid to gas, forming vapor 672. The mixture of vapor 672 and gas may be drawn through tile 601. Thus, heat is extracted from heat spreader 602 and, therefore, device component(s) 606. For example, for tile 601 including four cooling cells, each of which is analogous to cooling cell 501, a mixture of ninety percent water and ten percent alcohol may be used. Four cooling cells in tile 601 may provide a flow of 0.08 ml/sec. Using the corresponding phase change nominally one hundred and fifty Watts (e.g. at least one hundred and thirty Watts and not more than one hundred and eighty Watts) of heat may be removed by cooling system 600. Thus, using the liquid-vapor phase change of at least eighty degrees Celsius and not more than one hundred degrees Celsius (e.g. eighty-five through ninety or ninety-five degrees Celsius) may improve performance. If lower boiling points are desired (<80 C), organic liquids can be used for the thermal phase change process. Consequently, performance of a device incorporating cooling system 600 may be improved.

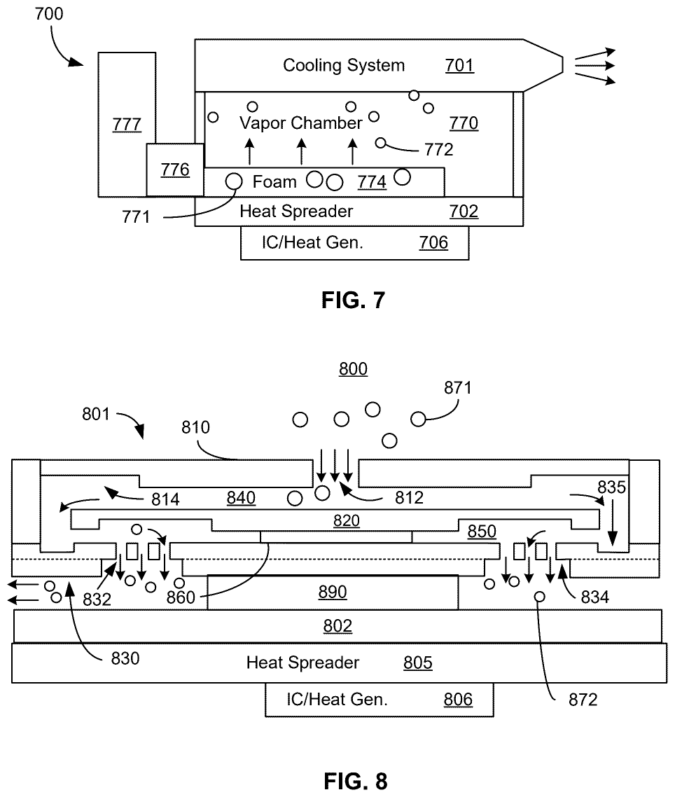

FIG. 7 depicts an embodiment of active MEMS cooling system 700 utilizing a phase change. Cooling system 700 is analogous to cooling systems 400, 500, and 600 as well as cooling systems 100, 200, and 300. Thus, analogous components are labeled similarly. MEMS cooling system 700 includes a cooling system 701 including multiple cooling cells coupled with heat-generating structure (e.g. heat spreader) 702, vapor chamber 770, metal foam 774, and liquid source 776 that are analogous to cooling cell(s) 401 and 501, heat-generating structure 402, 502, and 602, vapor chamber 470, 570, and 670, high-temperature foam 574 and 674, and liquid source 576 and 676, respectively. Also shown are device IC/heat-generating structure 706 and liquid reservoir 775. In some embodiments, a heat spreader analogous to device heat spreader 405 may be present. In some embodiments, cooling system 701 may include two, four, six, or another number of cooling cells. Such cooling cells are analogous to cooling cell(s) 500 and/or 301 as well as cooling system 100 and/or 200. The cooling cells of cooling system 701 are oriented as cooling cells 501. Thus, the mixture of vapor 772 and gas enters the cooling cells of tile 701 from vapor chamber 770. Liquid enters vapor chamber 570 via liquid source 576 and metal foam 574.

Cooling system 700 operates in a manner analogous to cooling systems 400, 500, and 600. Thus, cooling system 700 shares the benefits of cooling systems 400, 500, and/or 600. In addition, cooling system 701 directs the heated mixture outward to the side of cooling system 700. In some embodiments, cooling system 701 may have a spout and cover analogous to spout 380 and cover 306. Thus, not only may cooling system 700 more efficiently provide cooling, but also may direct the heated mixture of liquid vapor and gas in the desired direction.

FIG. 8 depicts an embodiment of active MEMS cooling system 800 utilizing a phase change. Cooling system 800 is analogous to cooling system 400 as well as cooling systems 100, 200, and 300. Thus, analogous components are labeled similarly. MEMS cooling system 800 includes cooling cell 801 coupled with heat-generating structure 802 that are analogous to cooling cell(s) 401 and heat-generating structure 402, respectively. Also shown is device heat spreader 805 and IC/heat-generating structure 806 that are analogous to device heat spreader/generator 405 and IC/heat-generating structure 406. Although not shown, cooling cell 801 may have a spout and cover analogous to spout 380 and cover 306. Cooling cell 801 includes top plate 810 having vent(s) 812, active element 820, orifice plate 830 including orifices 832, top chamber 840, bottom chambers 850 (together forming chamber 840/850), anchor (support structure) 860, and pedestal 890 that are analogous to top plate 110 having apertures 112, cooling element 120, orifice plate 130 having orifices 132, top chamber 140, bottom chamber 150, anchor 160, and pedestal 190. In some embodiments, a dust filter (not shown) may be provided for the aperture(s) 812. In the embodiment shown, top plate 810 includes cavities 814. Such cavities may facilitate the vibrational motion of active element 820. Although orifices 832 are shown in orifice plate 830, in some embodiments, orifices may be at the sidewalls of cooling cell 801.

Cooling cell 801 is oriented in a manner analogous to cooling cell 100. More specifically, cooling cell 801 is configured with orifices 832 closer to heat-generating structure 802 than aperture(s) 812. Cooling cell 801 may be considered to be inverted as compared to cooling cell 500.

In operation, liquid droplets 871 are provided proximate to aperture(s) 812. Thus, the liquid is provided as an aerosol. Active element 820 is activated and undergoes vibrational motion (e.g. in phase or out-of-phase motion of the cantilevered sections not pinned to anchor 860). The mixture of liquid droplets 871 and gas (e.g. air) is drawn in through aperture(s) 812, directed through chamber 840/850, and driven through out through orifices 832 by the vibrational motion of active element 820. The flow of liquid/vapor and gas is indicated by the arrows. Liquid droplets 871 are heated in cooling cell 801 and/or by heat-generating structure 802. If heated to the boiling temperature, liquid droplets 871 undergo a liquid to vapor phase change. Thus, vapor 872 is at least in the jet channel between heat-generating structure 802 and bottom plate 830.

Cooling system 800 may thus utilize simple heating of the mixture to transfer heat to the mixture. For simple heating, the amount of heat transferred to the fluid depends upon the specific heat of the fluid and the amount the temperature has been raised to transfer heat to the mixture. Cooling system 800 may also use a phase change (e.g., the liquid to gas phase change) to transfer a large amount of energy without a substantial increase in temperature. At least some of liquid 871 in cooling system 800 undergoes a phase change (i.e. from liquid to vapor 872) for heat-generating structure 802 being sufficiently hot. Further heating increases the temperature of the mixture (vapor 872 and gas that is not specifically shown).

Thus, using MEMS cooling system 800, significant amounts of heat may be removed from heat-generating structure 802 and components 806 and/or 406. Because MEMS cooling system 800 utilizes the change in phase of the liquid portion of the mixture, a large amount of heat may be removed from heat-generating structure 802 (e.g., a heat spreader) and, therefore, device component(s) 406 that are thermally connected to heat-generating structure 802. Consequently, thermal management may be greatly improved. Further, MEMS cooling system 800 is thin. For example, the thickness of MEMS system 800 may be analogous to the thickness of MEMS cooling system 400. Thus, in addition to providing significant cooling, MEMS cooling system 800 may have a low profile. Thus, MEMS cooling system 800 may be used in thin computing devices, in data centers (e.g. for cooling of components in racks), and/or other devices in which little space is available for cooling systems. Performance of such system may, therefore, be improved.

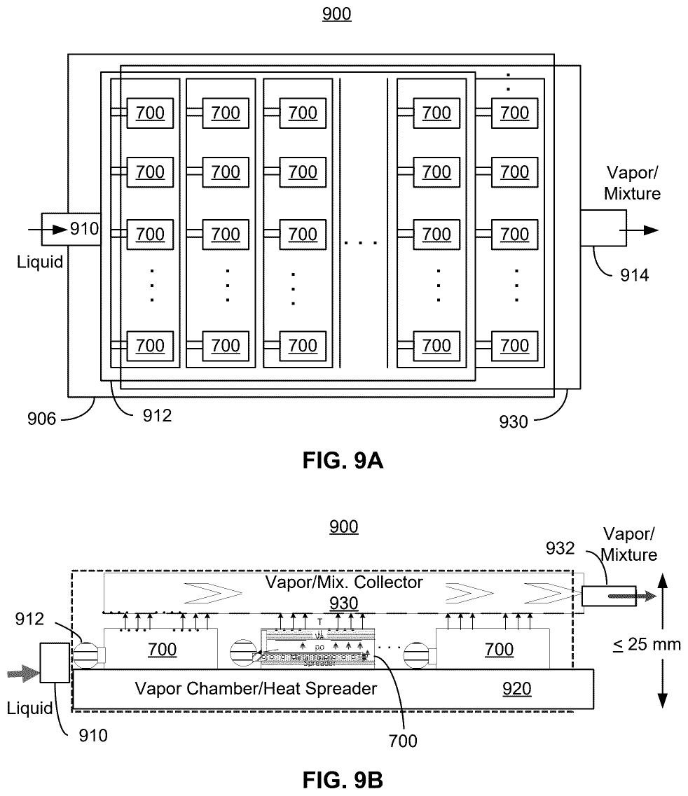

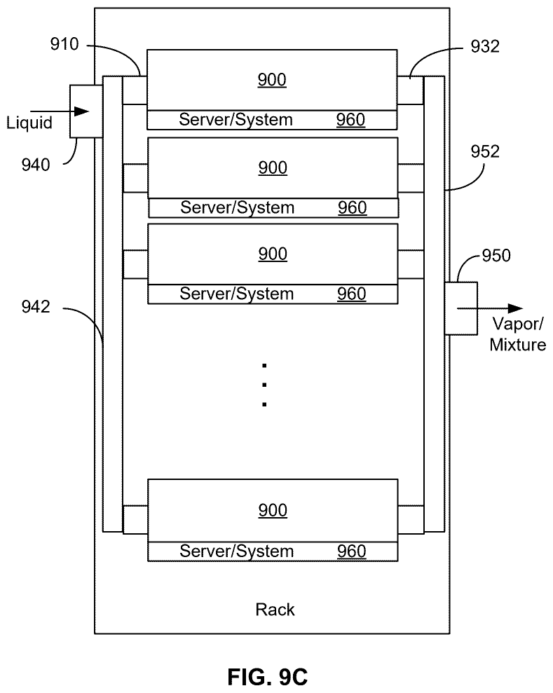

FIGS. 9A-9C depict embodiments of an active MEMS cooling system 900 utilizing a phase change and the environment in which the cooling system may be used. In particular, FIG. 9A depicts a plan view of system 900. FIG. 9B depicts a side view of a portion of system 900. FIG. 9C depicts a side, vertical view of a system using multiple systems 900.

In the embodiment shown, system 900 uses multiple MEMS cooling systems 700. In some embodiments, MEMS cooling system 700 may be replaced with MEMS cooling system(s) 400, 500, 600, and/or 800. System 900 also includes vapor chamber 920 that is thermally coupled (e.g. via thermal conduction) to device heat-generating structures (not shown) such as servers or racks in the system. In the embodiment shown, a 12×12 array of cooling systems analogous to cooling system 700 are present. In some embodiments, each cooling system 700 includes four cooling cells 500. System 900 may be seen as including a sheet of cooling systems for each level. As indicated in FIG. 9C, multiple sheets of cooling systems 900 may be present in multiple vertical layers of a rack. Each system 900 is coupled to a server system 960 via vapor chamber 920.

MEMS cooling systems 700 in system 900 operate as described herein. Thus, liquid is provided from a liquid source (indicated by an arrow) via delivery system 910 and 912. In some embodiments, 912 includes a sponge analogous to source 576. The liquid is also drawn into a component within MEMS cooling systems 700, such as a metal foam. Heat from the vapor chamber heats the liquid in the metal foam. If the vapor chamber is sufficiently hot, the liquid in the metal foam undergoes a phase change and becomes vapor. Motion of a cooling element draws the vapor up and may control the pressure within cooling system 700. The mixture of vapor and gas from multiple cooling systems 700 is provided to vapor collector 930. The heated mixture is output via ducting 932. In some embodiments, cool liquid is provided at one side of system 900 and the heated mixture of vapor and gas is output at the opposite side of cooling system 900. For example, cooling system 900 may be organized with a cool aisle (in which liquid is input) and a hot aisle (to which the heated mixture is output).

Cooling system 900 may efficiently manage heat, for example, for a rack in a data center. This may be indicated in FIG. 9C, in which multiple systems 900 are shown for multiple racks in a system. In some embodiments, a layer of one hundred and forty-four cooling systems 700 in combination with vapor chamber 920 and collector 930 may remove 20 kW of heat for a rack that is approximately eighty-five degrees Celsius. For a 1U server rack, twenty-seven racks may be present. In some embodiments, system 900 has three times the cooling capacity of liquid cooled systems. Further, significantly less liquid may be used by cooling system 900 than a liquid cooled system. In some embodiments, only four percent of the liquid used by a liquid cooling system is used by system 900. For example, a flow of 8 ml/second may be used instead of approximately 330 ml/second. Further, because the cooling systems used are thin (e.g. not more than 3-4 millimeters thick), the combination of the vapor chamber, vapor collector, and phase change cooling systems may be not thicker than 25 millimeters thick (as indicated in FIG. 9B). In other embodiments, other thicknesses are possible. For example, the size of a layer may be 600 millimeters×400 millimeters, ×25 millimeters in some embodiments. Thus, phase change cooling system 900 may not only more efficiently cool components, but also may be compact.

Thus, system 900 may effectively manage heat. The vapor expelled by system 900 may be hot (e.g. approximately eighty to eighty-five degrees Celsius). It may be desirable to recover some portion of this energy.

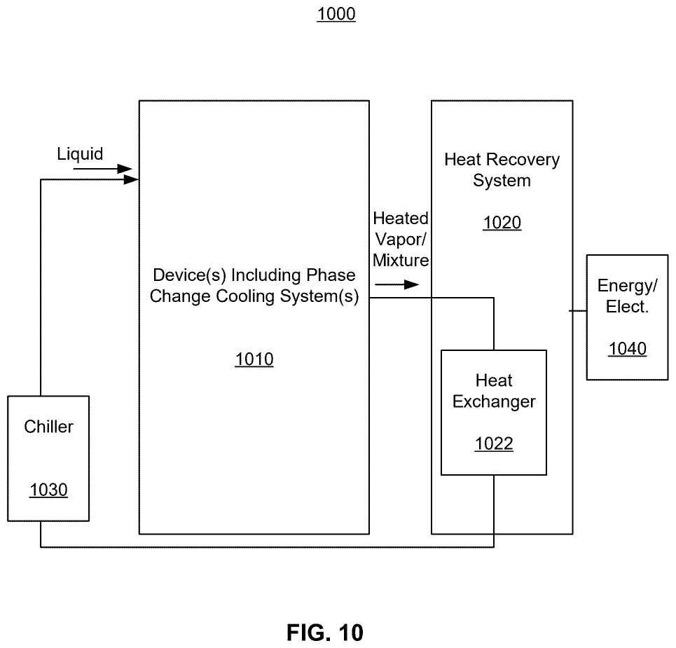

FIG. 10 depicts an embodiment of system 1000 that may use the heated vapor in order to perform useful work. System 1000 includes devices 1010 including MEMS phase change cooling system(s) such as systems 400, 500, 600, 700, 800, and/or 900. For example, devices 1010 may include the rack depicted in FIG. 9C. Devices 1010 are coupled with heat recovery system 1020 including heat exchanger 1022, and chiller 1030. Thus, system 100 is a closed system.

In operation, heated vapor from device(s) 1010 including MEMS cooling systems is output. The heated vapor (i.e. steam) may include 540 KW in heated vapor per system 900 (e.g. per rack). The heated vapor is provided to heat recovery system 1020. In some embodiments, heat recovery system 1020 is an organic Rankine cycle. Thus, heat recovery system 1020 may operate at vapor temperatures of less than one hundred degrees Celsius. Heat exchanger 1022 extracts heat from the vapor provided to heat recovery system 1020. Heat recovery system 1020 converts the heat to a usable form of energy (e.g. electricity). In some embodiments, approximately 150 kW of electricity (e.g. approximately 35 percent of the energy) may be generated by an organic Rankine cycle of heat recovery system 1020. Thus, energy 1040 may be output to another system for use. The temperature of the fluid is reduced in heat exchanger 1022. The fluid may be provided from heat exchanger 1022 to chiller 1030. Chiller 1030 cools the fluid. Thus, it may be ensured that the vapor is condensed back to liquid. The liquid may be provided back to devices 1010 for use in MEMS cooling systems therein. Thus, using system 1000, not only may heat be effectively managed in devices 1010, but the heat may be extracted may be used in performing useful work.

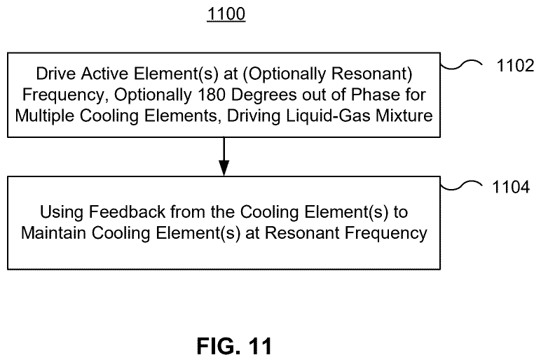

FIG. 11 is a flow chart depicting an embodiment of method 1100 for using an active MEMS cooling system utilizing a phase change. Method 1100 may include steps that are not depicted for simplicity. Method 1100 is described in the context of cooling devices 400, 500, 600, 700, and/or 900. However, method 1100 may be used with other cooling systems including but not limited to systems and cells described herein.

One or more of the active elements in a cooling system is actuated to vibrate, at 1102. At 1102, an electrical signal having the desired frequency is used to drive the active element(s). In some embodiments, the active elements are driven at or near structural and/or acoustic resonant frequencies at 1102. The driving frequency may be 15 kHz or higher. In some embodiments, the driving signal may be 20 kHz or higher. If multiple active elements are driven at 1102, the active elements may be driven out-of-phase. In some embodiments, the active elements are driven substantially at one hundred and eighty degrees out of phase. Further, in some embodiments, individual active elements are driven out-of-phase. For example, different portions of an active element may be driven to vibrate in opposite directions (i.e. analogous to a seesaw). In some embodiments, individual active elements may be driven in-phase (i.e. analogous to a butterfly). In addition, the drive signal may be provided to the anchor(s), the cooling element(s), or both the anchor(s) and the active element(s). Further, the anchor may be driven to bend and/or translate.

The vibrational motion of the active element(s) drives a mixture of a liquid and a gas through the cooling cells and proximate to a heat-generating structure. At least a portion of the liquid undergoes a liquid-vapor phase change. The liquid-vapor phase change transfers heat from the heat-generating structure to the mixture.

Feedback from the active element(s) may be used to adjust the driving current, at 1104. In some embodiments, the adjustment is used to maintain the frequency at or near the acoustic and/or structural resonant frequency/frequencies of the active element(s) and/or cooling system. Resonant frequency of a particular active element may drift, for example due to changes in temperature or changes in the active element itself. Adjustments made at 1104 allow the drift in resonant frequency to be accounted for.

For example, active element 520 may be driven to vibrate at 1102. In some embodiments, active element 520 is driven at or near resonance. Active element 520 draws a mixture of vapor 572 (from liquid 571 having undergone a phase change) and gas into chamber 540/550 and drives vapor 572 out through orifices 532. At 1104, the frequency of vibration of active element 520 may be adjusted using feedback. Thus, active element 520 may be kept at or near resonance. Thus, the mixture of vapor 572 and gas may be efficiently moved through system 500. Thus, the benefits of cooling system 500 may be achieved.

Although the foregoing embodiments have been described in some detail for purposes of clarity of understanding, the invention is not limited to the details provided. There are many alternative ways of implementing the invention. The disclosed embodiments are illustrative and not restrictive.

1. A cooling system, comprising:
a heat-generating structure; and
a cooling cell coupled with the heat-generating structure, the cooling cell including a chamber having an active element therein, the active element being configured to undergo vibrational motion when activated, the vibrational motion driving a mixture of a liquid and a gas through the chamber and proximate to the heat-generating structure;
wherein at least a portion of the liquid undergoes a liquid-vapor phase change, the liquid-vapor phase change transferring heat from the heat-generating structure to the mixture.

2. The cooling system of claim 1, wherein the mixture of the liquid and gas driven through the chamber by the vibrational motion includes a vapor phase of the liquid and the gas, and wherein the vibrational motion draws the vapor phase and the gas into and through the chamber.

3. The cooling system of claim 2, further comprising:
a vapor chamber between the heat-generating structure and the chamber, the vapor chamber including a high-temperature foam thermally coupled to the heat-generating structure, the portion of the liquid residing in the high-temperature foam undergoing the liquid-vapor phase change;
wherein the vibrational motion draws the vapor phase and the gas from the vapor chamber into the chamber.

4. The cooling system of claim 3, wherein the vibrational motion reduces a pressure in the vapor chamber below an inactive pressure corresponding to the active element being quiescent.

5. The cooling system of claim 4, wherein the vibrational motion reduces the pressure by at least 5 kPa.

6. The cooling system of claim 3, wherein the high-temperature foam is fluidically coupled with a liquid reservoir and physically coupled to the heat-generating structure.

7. The cooling system of claim 1, wherein the cooling cell is coupled with the heat-generating structure such that the vibrational motion draws droplets of the liquid and the gas into the chamber.

8. The cooling system of claim 1, further comprising:
a vapor collector coupled with the cooling cell, the vapor collector receiving the mixture and directing the mixture distal to the cooling cell, the mixture including the portion of the liquid in a vapor phase and the gas.

9. The cooling system of claim 1, further comprising:
a heat recovery subsystem coupled with the cooling cell, the heat recover subsystem receiving the portion of the liquid in a vapor phase.

10. The cooling system of claim 1, wherein the heat-generating structure includes a heat spreader.

11. A cooling system, comprising:
a heat-generating structure; and
a plurality of cooling cells coupled with the heat-generating structure, each of the plurality of cooling cells including a chamber having an active element therein, the active element being configured to undergo vibrational motion when activated, the vibrational motion driving a mixture of a liquid and a gas through the chamber and proximate to the heat-generating structure;
wherein at least a portion of the liquid undergoes a liquid-vapor phase change, the liquid-vapor phase change transferring heat from the heat-generating structure to the mixture.

12. The cooling system of claim 11, wherein the mixture of the liquid and gas driven through the chamber of each of the plurality of cooling cells by the vibrational motion includes a vapor phase of the liquid and the gas, and wherein the vibrational motion draws the vapor phase and the gas into and through the chamber.

13. The cooling system of claim 12, further comprising:
a vapor chamber between the heat-generating structure and the plurality of cooling cells, the vapor chamber including a high-temperature foam thermally coupled to the heat-generating structure, the portion of the liquid residing in the high-temperature foam undergoing the liquid-vapor phase change;
wherein the vibrational motion draws the vapor phase and the gas from the vapor chamber into the plurality of cooling cells.

14. The cooling system of claim 13, wherein the vibrational motion reduces a pressure in the vapor chamber below an inactive pressure corresponding to the active element being quiescent.

15. The cooling system of claim 14, wherein the vibrational motion reduces the pressure by at least 5 kPa.

16. The cooling system of claim 13, wherein the high-temperature foam is fluidically coupled with a liquid reservoir and physically coupled to the heat-generating structure.

17. The cooling system of claim 11, wherein the plurality of cooling cells is coupled with the heat-generating structure such that the vibrational motion draws droplets of the liquid and the gas into the chamber.

18. The cooling system of claim 11, further comprising:
a vapor collector coupled with the plurality of cooling cells, the vapor collector receiving the mixture and directing the mixture distal to the cooling cell, the mixture including the portion of the liquid in a vapor phase and the gas.

19. The cooling system of claim 1, further comprising:
a heat recovery subsystem coupled with the cooling cell, the heat recover subsystem receiving the portion of the liquid in a vapor phase.

20. A method, comprising:
driving an active element to induce a vibrational motion at a frequency, the active element being in a chamber of a cooling system, the active element being configured to undergo vibrational motion when activated, the vibrational motion driving a mixture of a liquid and a gas through the chamber and proximate to a heat-generating structure;
wherein at least a portion of the liquid undergoes a liquid-vapor phase change, the liquid-vapor phase change transferring heat from the heat-generating structure to the mixture.
